(19) United States
(12) Patent Application Publication
(10) Pub. No.: US 2023/0416466 A1
(43) Pub. Date: Dec. 28, 2023

(54) CURABLE RESIN COMPOSITION, SEMICONDUCTOR ENCAPSULATION MATERIAL, ADHESIVE, ADHESIVE FILM, PREPREG, INTERLAYER INSULATING MATERIAL, AND PRINTED-WIRING BOARD

(71) Applicant: Shin-Etsu Chemical Co., Ltd., Tokyo (JP)

(72) Inventors: Yoshihiro TSUTSUMI, Annaka-shi (JP); Yuki KUDO, Annaka-shi (JP); Tadaharu IKEDA, Annaka-shi (JP); Hiroyuki IGUCHI, Annaka-shi (JP); Atsushi TSUURA, Annaka-shi (JP)

(73) Assignee: Shin-Etsu Chemical Co., Ltd., Tokyo (JP)

(21) Appl. No.: 18/209,737

(22) Filed: Jun. 14, 2023

(30) Foreign Application Priority Data
Jun. 24, 2022 (JP) 2022-101901
Jun. 24, 2022 (JP) 2022-102006
Aug. 3, 2022 (JP) 2022-123707

(51) Int. Cl. C08G 73/10; C08J 5/24; H05K 1/03; C08L 79/08; C09J 179/08; C09J 7/35; H01L 23/29

(52) U.S. Cl. CPC C08G 73/1067; C08G 73/1021; C08J 5/244; H05K 1/0366; C08L 79/08; C09J 179/08; C09J 7/35; H01L 23/293

(57) ABSTRACT

Provided is a resin composition capable of being turned into a cured product exhibiting excellent dielectric properties even at high frequencies and small changes in dielectric properties even after being left under a high temperature for a long period. The resin composition is a curable resin composition containing:
(A) a maleimide compound represented by the following general formula (1)

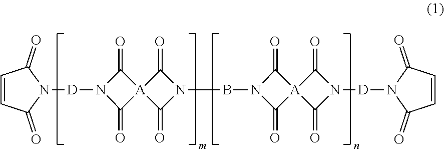

wherein D independently represents a dimer acid- and trimer acid-derived hydrocarbon group; B independently represents a cyclic structure-containing divalent hydrocarbon group other than a dimer acid- and trimer acid-derived hydrocarbon group; A independently represents a tetravalent organic group having a cyclic structure; m is 0 to 100, n is 0 to 100; and
(B) a catalyst,
wherein D in the formula (1) is a group in which dimer acid-derived hydrocarbon group occupies 95% by mass or more of the dimer acid- and trimer acid-derived hydrocarbon group, and is a hydrogenated group.

### BACKGROUND OF THE INVENTION

### Field of the Invention

The present invention relates to a curable resin composition, a semiconductor encapsulation material, an adhesive, an adhesive film, a prepreg, an interlayer insulating material, and a printed-wiring board.

### Background Art

In recent years, a next-generation communication system known as 5G (millimeterwave region of 26 to 80 GHz) has prevailed, and even a next-next-generation communication system called 6G is already under development, where attempts are being made to realize a communication with a higher speed, a larger capacity and a lower latency than ever before. The realization of these communication systems requires materials for use in a high-frequency band of 3 to 80 GHz, and it is critical to reduce a transmission loss as a countermeasure for noise.

A transmission loss is a sum of a conductor loss and a dielectric loss; it is necessary to lower the roughness of the surface of a metal foil used to reduce a conductor loss. Meanwhile, since a dielectric loss is proportionate to a product of a square root of a relative permittivity and a dielectric tangent, as an insulating material, it is demanded that there be developed one with excellent dielectric properties (i.e. with a low relative permittivity and a low dielectric tangent).

Particularly, it is for substrate purposes that such insulating material with excellent dielectric properties is required. There are now increasingly employed a product known as a reactive polyphenylene ether resin (PPE) in the case of a rigid substrate; and products known as a liquid crystal polymer (LCP) and a modified polyimide (MPI) with improved properties in the case of a flexible printed-circuit board (FPC).

In this regard, reports have been made on substantially using, as a main resin of a substrate, a dimer diamine frame (dimer acid-derived frame)-containing maleimide compound (specific maleimide compound) (JP-A-2016-131243, JP-A-2016-131244, WO2016/114287, and JP-A-2018-201024). As opposed to the properties of a general maleimide resin, while a specific maleimide compound has a low glass-transition temperature (Tg) and a high coefficient of thermal expansion (CTE), it also has a number of merits such as significantly excellent dielectric properties, a flexible property, an excellent adhesion force to metals or the like, and a capability of realizing multi (high)-layering as being a heat-curable resin; a wide range of researches and developments are conducted with regard to such specific maleimide compound. However, each of these specific maleimide compounds has been mainly used alone.

Further, as described above, since a dielectric loss is proportionate to a ratio between a square root of a relative permittivity and a dielectric tangent, it is now more important to lower the dielectric tangent.

Meanwhile, it has been reported that a resin material using a trimer triamine frame (trimer acid-derived frame)-containing maleimide compound as the main resin for a substrate is superior in, for example, heat resistance, mechanical strength and dielectric properties (JP-A-2019-182932 and Wo2020/45408). In general, dimer acid and trimer acid are in the form of a mixture, and are often collectively referred to as dimer acid. Further, dimer diamine and trimer triamine that are derived from dimer acid and trimer acid are likewise collectively referred to as dimer diamine; even in the cases of commercially available products of compounds referred to as dimer diamines, it is well known that a ratio between dimer diamine and trimer triamine varies on a product-by-product basis (JP-A-2017-186551, and The Society of Synthetic Organic Chemistry, Japan Journals, 1967, 25(2), 180-183).

As mentioned above, specific maleimide compounds are generally characterized by having a low Tg and a high CTE, where the maleimide compound of WO2020/45408 has a high Tg of 80° C. or higher. This high Tg of 80° C. or higher is achieved by increasing the ratio of trimer triamine and the cross-link density.

Further, in WO2019/189467, there is used a maleimide compound having a frame derived from a dimer diamine and a frame derived from a particular diamine other than a dimer diamine, whereby a lower CTE can be achieved in the case of a resin material containing such maleimide compound. A compound of such concept has also already been reported in Wo2015/48575 and others, and has also been placed on the market (“TECH DATA SHEET BMI-2500,” [online], DESIGNER MOLECULES INC, Nov. 23, 2016, [search conducted on Jul. 13, 2018], internet <URL: https://www.designermoleculesinc.com/FTP/TDS %20Tech%20Data%20Sheet%20Files/BMI-2500%20(R1316)%20-%20Imide%20Extended%20BMI.pdf>).

### SUMMARY OF THE INVENTION

Against this background, as a result of synthesizing and examining these maleimide compounds having trimer triamine frame-derived structures, it became clear that a composition containing any of these compounds has an issue with workability and flowability due to the high viscosities of these compounds; and that a cured product of such composition exhibits a large relative permittivity and dielectric tangent at a high frequency, is highly susceptible to moisture absorption, easily exhibits warpage and cracks due to its high storage elastic modulus and hardness, and has a poor heat resistance as indicated by a significant impact when heated.

Moreover, even in the cases of specific maleimide compounds having the properties described above, certain aspects of these maleimide compounds are insufficient in terms of property; there is a demand for and an urgent need to develop a maleimide compound capable of yielding a cured product having excellent dielectric properties (low relative permittivity, low dielectric tangent, low frequency dependency, high heat resistance), and even a high adhesion force to a metal such as copper, while having a higher Tg and a lower CTE.

Thus, it is an object of the present invention to provide a curable resin composition that has an excellent workability and flowability due to a low viscosity of a maleimide compound contained therein as a base resin, and is capable of being turned into a cured product exhibiting excellent dielectric properties even at high frequencies, showing small changes in dielectric properties even after being left under a high temperature for a long period of time, and being less susceptible to moisture absorption; and a semiconductor encapsulation material, adhesive, adhesive film, prepreg, interlayer insulating material and printed-wiring board containing such curable resin composition or the cured product thereof.

Further, it is another object of the present invention to provide a curable resin composition that is capable of being turned into a cured product exhibiting a small warpage due to its low elasticity and low hardness, an excellent crack resistance, excellent dielectric properties even at high frequencies, and small changes in dielectric properties even after being left under a high temperature for a long period of time; and a semiconductor encapsulation material, adhesive, adhesive film, prepreg, interlayer insulating material and printed-wiring board containing such curable resin composition or the cured product thereof.

Furthermore, it is yet another object of the present invention to provide a curable resin composition that is capable of being turned into a cured product having excellent dielectric properties (low relative permittivity, low dielectric tangent, low frequency dependency, high heat resistance), and even a high adhesion force to a metal such as copper, while having a higher Tg and a lower CTE; and a semiconductor encapsulation material, adhesive, adhesive film, prepreg, interlayer insulating material and printed-wiring board containing such curable resin composition or the cured product thereof.

The inventors of the present invention diligently conducted a series of studies to solve the above problems, and completed the invention by finding that the resin composition shown below was able to achieve the above objects.

That is, the present invention is to provide the following curable resin composition and others.

[1]

A curable resin composition containing:
(A) a maleimide compound represented by the following general formula (1)

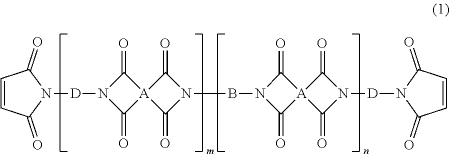

wherein D independently represents a dimer acid- and trimer acid-derived hydrocarbon group; B independently represents a cyclic structure-containing divalent hydrocarbon group other than a dimer acid- and trimer acid-derived hydrocarbon group; A independently represents a tetravalent organic group having a cyclic structure; m is 0 to 100, n is 0 to 100, where no restrictions are imposed on an order of each repeating unit identified by m and n, and a bonding pattern may be alternate, block or random; and
(B) a catalyst,

wherein D in the formula (1) is a group in which dimer acid-derived hydrocarbon group occupies 95% by mass or more of the dimer acid- and trimer acid-derived hydrocarbon group, and is a hydrogenated group.

[2]

The curable resin composition according to [1], wherein the maleimide compound as the component (A) is a compound represented by the following formula (1-1) when m=n=0 in the formula (1)

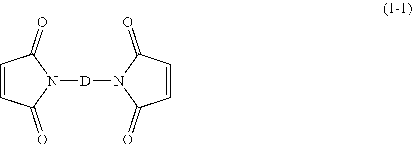

wherein D represents a dimer acid- and trimer acid-derived hydrocarbon group.

[3]

The curable resin composition according to [2], wherein the maleimide compound as the component (A) has a viscosity of not higher than 7.0 Pa s when measured by a method described in JIS Z8803:2011 and by a Brookfield-type rotary viscometer at a measurement temperature of 25° C. and a spindle rotation speed of 5 rpm.

[4]

The curable resin composition according to [2] or [3], wherein the maleimide compound as the component (A) has a number average molecular weight of not larger than 1,150.

[5]

The curable resin composition according to [1], wherein the maleimide compound as the component (A) is a compound represented by the following formula (1-2) when m is not 0, but n=0 in the formula (1)

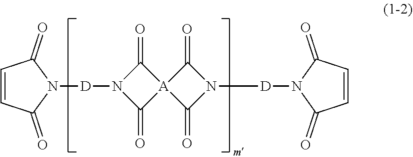

wherein D independently represents a dimer acid- and trimer acid-derived hydrocarbon group, A independently represents a tetravalent organic group having a cyclic structure, m′ is 1 to 100.

[6]

The curable resin composition according to [5], wherein a cured product of the curable resin composition has a storage elastic modulus of smaller than 1,000 MPa when measured by a method described in JIS K7244-4:1999 and by a dynamic mechanical analyzer at a frequency of 10 Hz and a temperature rising rate of 5° C./min in a temperature range of −50 to 200° C.

[7]

The curable resin composition according to [5] or [6], wherein a cured product of the curable resin composition has a hardness of not higher than D50 when measured by a method described in JIS K 6253-3:2012 and by a type D durometer at a measurement temperature of 25° C.

[8]

The curable resin composition according to [1], wherein the maleimide compound as the component (A) is a compound represented by the following formula (1-3) when neither m nor n is 0 in the formula (1)

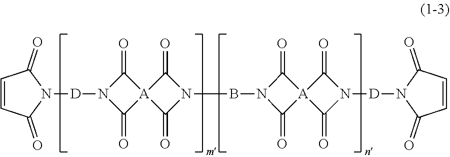

wherein D independently represents a dimer acid- and trimer acid-derived hydrocarbon group; B independently represents a cyclic structure-containing divalent hydrocarbon group other than a dimer acid- and trimer acid-derived hydrocarbon group; A independently represents a tetravalent organic group having a cyclic structure; m′ is 1 to 100, n′ is 1 to 100, where no restrictions are imposed on an order of each repeating unit identified by m′ and n′, and a bonding pattern may be alternate, block or random.

[9]

The curable resin composition according to [8], wherein a molar ratio between the group D and the group B in the maleimide compound as the component (A) is D/B=20/80 to 65/35.

[10]

The curable resin composition according to [9], wherein B in the formula (1) is a group having an aliphatic ring and/or an aromatic ring.

[11]

The curable resin composition according to any one of [8] to [10], wherein A in the formula (1) is any one of the tetravalent organic groups represented by the following structural formulae

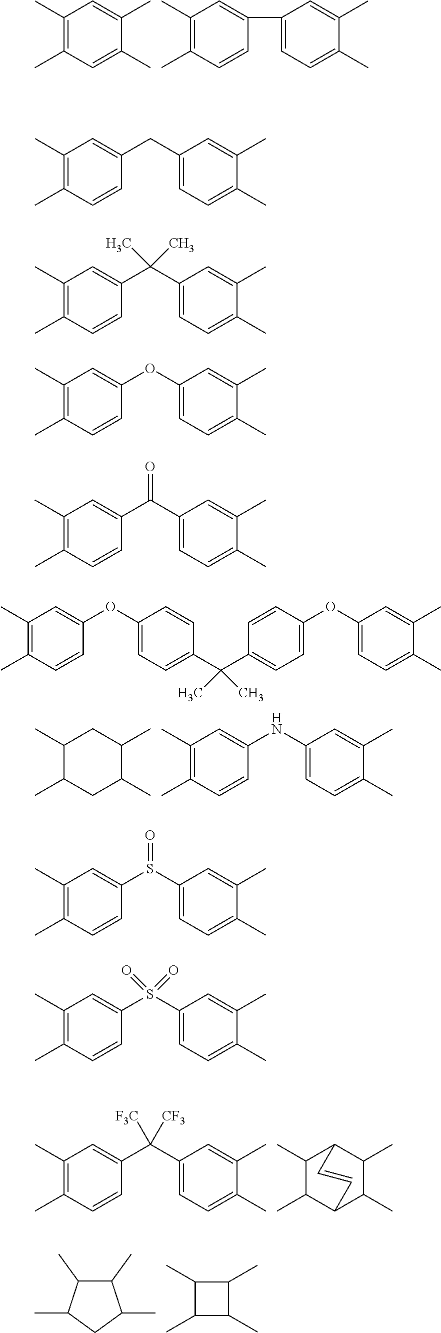

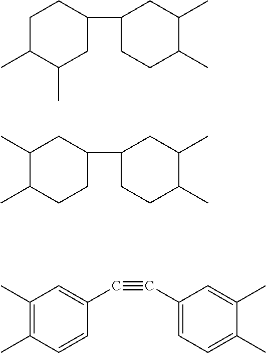

wherein bonds that are yet unbonded to substituent groups are to be bonded to carbonyl carbons forming cyclic imide structures in the formula (1-3).

[12]

The curable resin composition according to any one of [8] to [11], wherein the curable resin composition has a glass-transition temperature of higher than 120° C. when measured by dynamic mechanical analysis (DMA) after curing.

[13]

The curable resin composition according to any one of [1] to [12], wherein the catalyst as the component (B) is at least one selected from an organic peroxide, an anionic polymerization initiator and a photocuring initiator.

[14]

A semiconductor encapsulation material containing the curable resin composition according to any one of [1] to [12].

[15]

An adhesive containing the curable resin composition according to any one of [1] to [12].

[16]

An adhesive film containing the curable resin composition according to any one of [1] to [12].

[17]

A prepreg containing the curable resin composition according to any one of [1] to [12] and a fiber base material.

[18]

An interlayer insulating material containing the curable resin composition according to any one of [1] to [12].

[19]

A printed-wiring board containing a cured product of the curable resin composition according to any one of [1] to [12].

One embodiment of the present invention is a curable resin composition that has an excellent workability and flowability due to a low viscosity of a maleimide compound contained therein as a base resin, and exhibits, after curing, excellent dielectric properties both at high frequencies and after being left under a high temperature for a long period of time, and a small susceptibility to moisture absorption.

Further, another embodiment of the present invention is a curable resin composition that is capable of being turned into a cured product exhibiting a small warpage due to its low elasticity and low hardness, an excellent crack resistance, excellent dielectric properties even at high frequencies, and small changes in dielectric properties even after being left under a high temperature for a long period of time.

Furthermore, yet another embodiment of the present invention is a curable resin composition that is capable of being turned into a cured product having excellent dielectric properties (low relative permittivity, low dielectric tangent, low frequency dependency, high heat resistance), and even a high adhesion force to a metal such as copper, while having a higher Tg and a lower CTE.

Thus, the resin composition of the present invention is suitable for use in a semiconductor encapsulation material, adhesive, adhesive film, prepreg, interlayer insulating material and printed-wiring board.

### BRIEF DESCRIPTION OF THE DRAWINGS

FIG. 1 shows a cut end surface of one example of a prepreg of the present invention.

FIG. 2 shows a cut end surface of one example of a laminate of the present invention.

FIG. 3 shows a cut end surface of one example of a printed-wiring board of the present invention.

### DETAILED DESCRIPTION OF THE INVENTION

The present invention is described in greater detail hereunder.

### (A) Maleimide Compound Represented by the Following General Formula (1)

A component (A) is a maleimide compound represented by the following general formula (1).

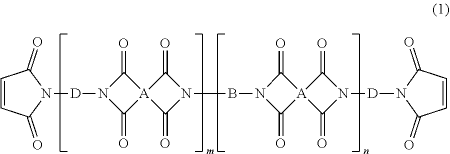

In the formula (1), D independently represents a dimer acid- and trimer acid-derived hydrocarbon group; B independently represents a diamine-derived frame other than a dimer acid frame; A independently represents a tetravalent organic group having a cyclic structure; m is 0 to 100, n is 0 to 100, where no restrictions are imposed on an order of each repeating unit identified by m and n, and a bonding pattern may be alternate, block or random.

As for D in the formula (1), dimer acid-derived hydrocarbon group occupies 95% by mass or more of the dimer acid- and trimer acid-derived hydrocarbon group. Below, such ratio of dimer acid-derived hydrocarbon group in the dimer acid- and trimer acid-derived hydrocarbon group may simply be referred to as “dimer ratio” or “dimer:trimer.”

When this dimer ratio is 95% by mass or more, there will be advantages such as that the maleimide compound as the component (A) will exhibit a low viscosity whereby a handling property of the compound itself will excel, and that a high moldability will be achieved when in the state of a composition. The dimer ratio is 95% by mass or more, preferably 96% by mass or more, more preferably 97% by mass or more, even more preferably 98% by mass or more, particularly preferably 99% by mass or more.

Further, D in the formula (1) is a hydrogenated group. That is, as described later, while double bonds may be contained in a group corresponding to the group D of an amine compound as a raw material of the component (A), the double bonds are to be reduced by hydrogenation before using the amine compound as the raw material. By reducing the double bonds in the group D, oxidation of the double bonds can be suppressed whereby deterioration by heat as well as deterioration in dielectric properties caused thereby can be avoided.

Here, in this specification, the dimer ratio is a value calculated from a peak area ratio in a gas chromatography (GC) measurement conducted under the following measurement conditions.

### Measurement Conditions:

Device: GC-2014 (by SHIMADZU CORPORATION)
Column: DB-5 30 m×0.25 mm×0.25 μm
Gasification chamber temperature: 280° C.
Temperature: 50° C.→10° C./min→300° C., maintained for 20 min
Column flow rate: 1.00 mL/min
Purge flow rate: 3.00 mL/min

As mentioned above, dimer acid and trimer acid are in general present in a mixed form, and are often collectively referred to as dimer acid. Further, dimer diamine and trimer triamine that are derived from dimer acid and trimer acid are likewise collectively referred to as dimer diamine; even in the cases of commercially available products of compounds referred to as dimer diamines, it is well known that a ratio between dimer diamine and trimer triamine varies on a product-by-product basis.

A dimer acid here refers to a liquid dibasic acid whose main component is a dicarboxylic acid having 36 carbon atoms, which is produced by dimerizing an unsaturated fatty acid having 18 carbon atoms and employing a natural substance such as a vegetable fat or oil as its raw material. A dimer acid may contain multiple structures as opposed to one single type of frame, and there exist several types of isomers. Typical dimer acids are categorized under the names of (a) linear type, (b) monocyclic type, (c) aromatic ring type, and (d) polycyclic type.

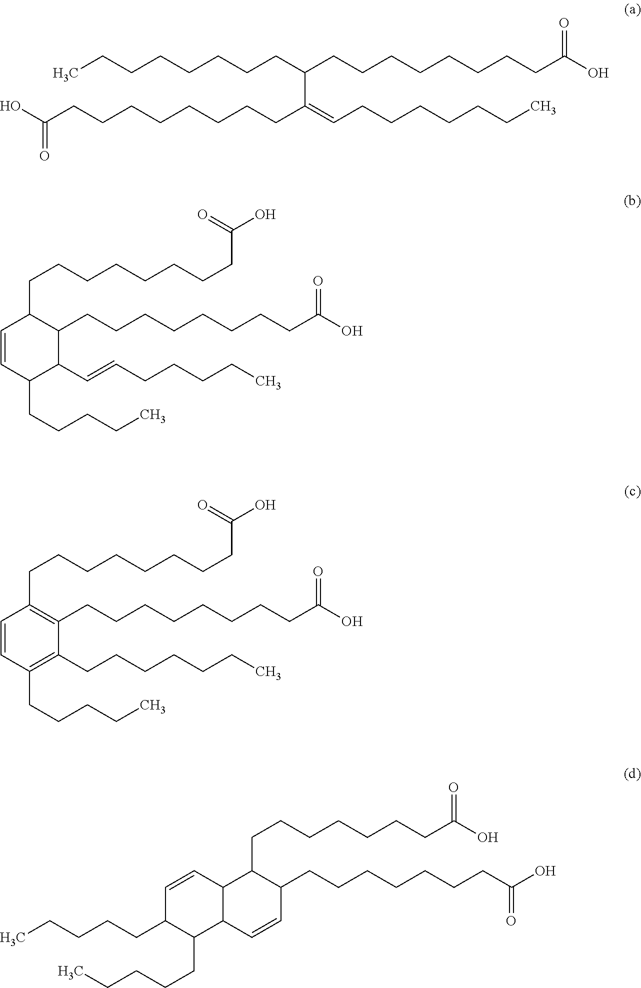 [SMILES: CCCCCCC/C=C(/CCCCCCCCC(=O)O)C(CCCCCCCC)CCCCCCCCC(=O)O ; CCCCC/C=C/C1C(CCCCC)C=CC(CCCCCCCCC(=O)O)C1CCCCCCCCC(=O)O ; CCCCCCCc1c(CCCCC)ccc(CCCCCCCCC(=O)O)c1CCCCCCCCC(=O)O ; CCCCCC1C=CC2C(C=CC(CCCCCCCC(=O)O)C2CCCCCCCC(=O)O)C1CCCCC]

Further, a trimer acid is a by-product obtained at the time of producing the above dimer acid(s); as is the case with dimer acid, a trimer acid may contain multiple structures as opposed to one single type of structure, and there exist several types of isomers. A typical structure thereof may be one expressed by the following formula (e).

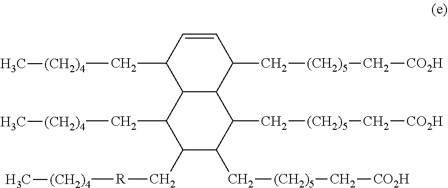

R in the formula (e) represents an ethylene group or an ethenylene group.

B in the formula (1) independently represents a cyclic structure-containing divalent hydrocarbon group other than a dimer acid- and trimer acid-derived hydrocarbon group. B in the formula (1) is a cyclic structure-containing divalent hydrocarbon group having preferably 3 to 550, more preferably 6 to 30 carbon atoms. The cyclic structure in B may be an aliphatic ring, an aromatic ring, or both an aliphatic ring and an aromatic ring; there may be only one cyclic structure or two or more identical or different types of cyclic structures in B.

As described above, B in the formula (1) is a group other than a dimer acid- and trimer acid-derived hydrocarbon group; that is, B is a group derived from a diamine compound other than a dimer diamine and trimer triamine. Examples of such diamine compound other than a dimer diamine and trimer triamine include aromatic diamine compounds such as 2,2-bis(4-(4-aminophenoxy)phenyl)propane, 4,4′-diamino-3,3′-dimethyldiphenylmethane, 4,4′-diamino-3,3′-diethyldiphenylmethane, 4,4′-diaminodiphenyl ether, 4,4′-diamino-3,3′,5,5′-tetraethyldiphenylmethane, bis[4-(4-aminophenoxy)phenyl]sulfone, 4,4′-diaminodiphenylmethane, and 1,3-bis(4-aminophenoxy)benzene; cyclohexane ring-containing diamine compounds such as 1,3-bis(aminomethyl)cyclohexane, 1,4-bis(aminomethyl)cyclohexane, 1,3-cyclohexanediamine, 1,4-cyclohexanediamine, isophoronediamine, 4,4′-methylenebis(cyclohexylamine), and 4,4′-methylenebis(2-methylcyclohexylamine); and aromatic ring- and cyclohexane ring-containing diamine compounds such as 1,1-bis(4-aminophenyl)cyclohexane.

In the formula (1), A independently represents a tetravalent organic group having a cyclic structure; particularly, it is preferred that A be any one of the tetravalent organic groups represented by the following structural formulae.

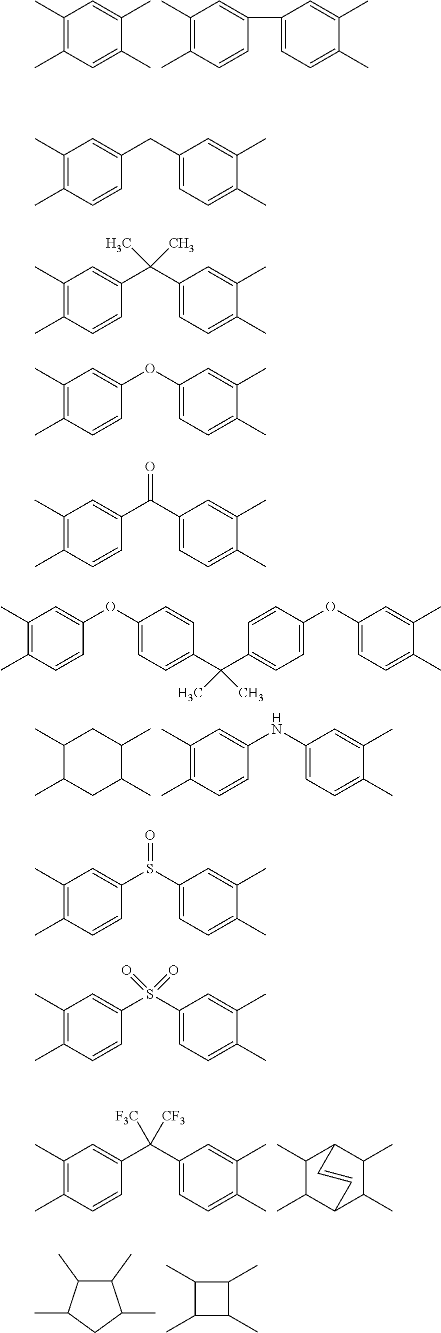

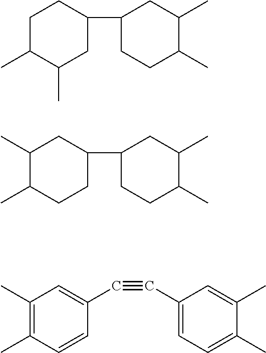

Bonds in the above structural formulae that are yet unbonded to substituent groups are to be bonded to carbonyl carbons forming cyclic imide structures in the formula (1).

In one embodiment of the present invention, the component (A) is a maleimide compound represented by the following formula (1-1) when m=n=0 in the formula (1).

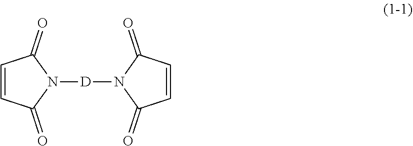

In the formula (1-1), D is defined as above in the formula (1).

Further, for the sake of handling property at room temperature, it is preferred that the maleimide compound as the component (A) that is represented by the formula (1-1) have a viscosity of not higher than 7.0 Pa s, more preferably not higher than 6.0 Pa s, when measured by the following method. A viscosity of not higher than 7.0 Pa s is preferable, because there will be achieved an improved moldability, an improved wettability to a base material, and an improved adhesion force.

Measurement conditions: measurement is conducted by a method described in JIS Z8803:2011 and by a Brookfield-type rotary viscometer at a measurement temperature of 25° C. and a spindle rotation speed of 5 rpm.

In order to adjust the viscosity of the maleimide compound as the component (A) that is represented by the formula (1-1) to 7.0 Pa s or lower when measured under the above conditions, it will suffice to employ a group D that has been hydrogenated and has a dimer ratio of 95% by mass or more, in the maleimide compound of the formula (1-1); the higher the hydrogenation rate is and the higher the dimer ratio is, the more preferable it is.

The number average molecular weight of the maleimide compound as the component (A) that is represented by the formula (1-1) is preferably not larger than 1,150, more preferably not larger than 1,100.

Here, the number average molecular weight mentioned in the present invention refers to a number average molecular weight that is measured by gel permeation chromatography (GPC) under the following conditions, using polystyrene as a reference substance.

### Measurement Conditions

Developing solvent: Tetrahydrofuran (THF)
Flow rate: 0.35 mL/min
Detector: Differential refractive index detector (RI)
Column: TSK Guardcolumn Super H-L
   TSK gel Super HZ4000 (4.6 mm I.D.×15 cm×1)
   TSK gel Super HZ3000 (4.6 mm I.D.×15 cm×1)
   TSK gel Super HZ2000 (4.6 mm I.D.×15 cm×2)
(All manufactured by Tosoh Corporation)
Column temperature: 40° C.
Sample injection volume: 5 μL (THF solution with a concentration of 0.2% by mass)

Further, in another embodiment of the present invention, the component (A) is a maleimide compound represented by the following formula (1-2) when m is not 0, but n=0 in the formula (1).

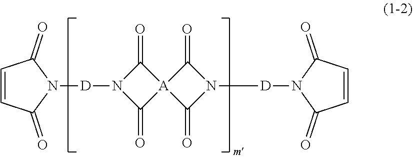

In the formula (1-2), D and A are defined as above in the formula (1); m′ is 1 to 100, preferably 3 to 50. It is preferable when m′ is within these ranges, because the resin composition will exhibit a high strength even when in an uncured state, and a favorable solvent solubility can be achieved as well.

The maleimide compound represented by the formula (1-2) may be a commercially available product such as BMI-1500, BMI-3000 (all by Designer Molecules Inc.), or one synthesized by a later-described method.

Further, in yet another embodiment of the present invention, the component (A) is a maleimide compound represented by the following formula (1-3) when neither m nor n is 0 in the formula (1).

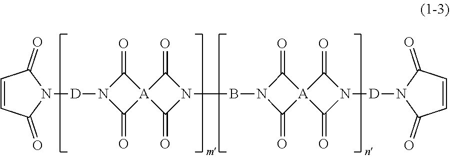

In the formula (1-3), D, A and B are defined as above in the formula (1); m′ is 1 to 100, preferably 1 to 60, more preferably 1 to 50; n′ is 1 to 100, preferably 1 to 60, more preferably 3 to 50.

In the formula (1-3), an excessively large m′ and n′ may lead to an impaired fluidity and a poor moldability accordingly.

No restrictions are imposed on an order of each repeating unit identified by m′ and n′, and a bonding pattern may be alternate, block or random; a block bonding pattern is preferred in terms of ease in achieving a higher Tg.

By using such maleimide compound represented by the formula (1-3), and due to the dimer acid frame-containing maleimide compound, there can be obtained a composition having excellent dielectric properties (low relative permittivity, low dielectric tangent, low frequency dependency, high heat resistance) and a high adhesion force to a metal such as copper, while having a high Tg and a low CTE.

Since the maleimide compound as the component (A) that is represented by the formula (1-3) has in its molecule D and B which are different groups, a curable resin composition containing such maleimide compound can be turned into a cured product having excellent dielectric properties, a high adhesiveness, a high Tg and a low CTE.

In the maleimide compound as the component (A) that is represented by the formula (1-3), a molar ratio between the group D and the group B is preferably D/B=20/80 to 65/35, more preferably 25/75 to 60/40. A low ratio of the group D in the molecule may lead to impaired dielectric properties and a susceptibility to moisture absorption, and may even make it difficult to synthesize the component (A) due to a poor solubility in a solvent. Meanwhile, a high ratio of the group D in the molecule may lead to a lower Tg, a larger CTE, and a poor dimension stability of the cured product accordingly.

There are no particular restrictions on the number average molecular weight of the maleimide compound as the component (A) that is represented by the formula (1-3); in terms of handling property of the composition, the number average molecular weight of this maleimide compound is preferably 800 to 50,000, more preferably 1,000 to 30,000.

The component (A) used in the present invention can be produced by employing, as a raw material, a mixture of the dimer diamine derived from the above dimer acid and the trimer triamine derived from the above trimer acid (the mixture is referred to as mixture of dimer diamine and trimer triamine hereunder). Here, a dimer diamine derived from a dimer acid is one having a structure in which the two carboxy groups in the dimer acid have each been substituted by a primary aminomethyl group; similarly, a trimer triamine derived from a trimer acid is one having a structure in which the three carboxy groups in the trimer acid have each been substituted by a primary aminomethyl group. In this regard, the notion that D in the formula (1) represents a dimer acid- and trimer acid-derived hydrocarbon group means that the group D is derived from the mixture of these dimer diamine derived from the dimer acid and trimer triamine derived from the trimer acid.

Specific examples of a method for producing the component (A) are as follows.

Production method 1. As a method for producing the maleimide compound represented by the formula (1-1), there may, for example, be employed a method where the mixture of dimer diamine and trimer triamine is reacted with maleic anhydride.

Production method 2. As a method for producing the maleimide compound represented by the formula (1-2), there may, for example, be employed a method where the mixture of dimer diamine and trimer triamine, a cyclic structure-containing tetracarboxylic dianhydride, and maleic anhydride are reacted with one another.

Production method 3. As a method for producing the maleimide compound represented by the formula (1-3), there may, for example, be employed a method where the mixture of dimer diamine and trimer triamine, a cyclic structure-containing tetracarboxylic dianhydride, a diamine other than dimer diamine and trimer triamine, and maleic anhydride are reacted with one another.

These reactions can be performed in accordance with a known method for synthesizing a polyimide, where an amic acid is synthesized from a diamine and a carboxylic anhydride, and this amic acid is then subjected to a dehydration reaction.

That is, in the case of the production method 1, the method listed serves as an example of a method where a maleamic acid is synthesized by reacting the mixture of dimer diamine and trimer triamine with maleic anhydride, and then subjected to a ring-closing and dehydration reaction.

Further, in the case of the production method 2, the method listed serves as an example of a method where an amic acid is synthesized from the mixture of dimer diamine and trimer triamine and a cyclic structure-containing tetracarboxylic dianhydride before being subjected to a ring-closing and dehydration reaction, followed by further reacting the product with maleic anhydride to synthesize a maleamic acid and then subject the same to a ring-closing and dehydration reaction.

Furthermore, in the case of the production method 3, the method listed serves as an example of a method where an amic acid is synthesized from the mixture of dimer diamine and trimer triamine and a cyclic structure-containing tetracarboxylic dianhydride before being subjected to a ring-closing and dehydration reaction, followed by adding a diamine other than dimer diamine and trimer triamine to synthesize an amic acid and then subject the same to a ring-closing and dehydration reaction, and then followed by further reacting the product with maleic anhydride to synthesize a maleamic acid and then subject the same to a ring-closing and dehydration reaction. Moreover, there may be employed a similar method where the order in which the mixture of dimer diamine and trimer triamine and a diamine other than dimer diamine and trimer triamine are added is modified.

The reaction for synthesizing the (male)amic acid usually proceeds in an organic solvent (e.g. nonpolar solvent or high-boiling-point aprotic polar solvent) at a temperature of 25° C. (room temperature) to 100° C. The subsequent ring-closing and dehydration reaction of the amic acid is such that after reacting at 90 to 120° C., the reaction is then allowed to proceed while removing, from the system, water as a by-product produced in the condensation reaction. An organic solvent (e.g. nonpolar solvent, high-boiling-point aprotic polar solvent) and an acid catalyst may be added to promote the ring-closing and dehydration reaction. Examples of such organic solvent may include toluene, xylene, anisole, biphenyl, naphthalene, N,N-dimethylformamide (DMF), and dimethylsulfoxide (DMSO). Any one kind of them may be used alone, or two or more kinds of them may be used in combination. Further, examples of such acid catalyst may include sulfuric acid, methanesulfonic acid, and trifluoromethanesulfonic acid. Any one kind of them may be used alone, or two or more kinds of them may be used in combination.

In the production method 1, a molar ratio between maleic anhydride and the mixture of dimer diamine and trimer triamine is preferably maleic anhydride/mixture of dimer diamine and trimer triamine=6.0 to 2.2/1.0.

In the production method 2, a molar ratio between the cyclic structure-containing tetracarboxylic dianhydride and the mixture of dimer diamine and trimer triamine is preferably cyclic structure-containing tetracarboxylic dianhydride/mixture of dimer diamine and trimer triamine=0.5 to 0.999/1.0.

Further, as for maleic anhydride added later, it is preferred that maleic anhydride be added in an amount at which a molar ratio between maleic anhydride and the mixture of dimer diamine and trimer triamine will be maleic anhydride/mixture of dimer diamine and trimer triamine=0.1 to 10.0/1.0.

In the production method 3, a molar ratio between the cyclic structure-containing tetracarboxylic dianhydride and the diamine that is to be reacted with the tetracarboxylic dianhydride at first is preferably cyclic structure-containing tetracarboxylic dianhydride/diamine=1.01 to 1.50/1.0.

Further, as for the diamine added later, it is preferred that this diamine be added in an amount of 1.6 to 2.5 mol per 1 mol of the product obtained in the previous step.

Furthermore, as for maleic anhydride added even later, it is preferred that maleic anhydride be added in an amount of 1.6 to 2.5 mol per 1 mol of the product obtained in the previous step.

In the above reaction(s), the ratio between dimer diamine and trimer triamine in the mixture of dimer diamine and trimer triamine as the raw material, and whether or not the mixture has been hydrogenated shall be directly reflected in the maleimide compound obtained. Thus, in terms of productivity, as the mixture of dimer diamine and trimer triamine which serves as a raw material, it is preferred that there be used one that has a dimer ratio of 95% by mass or more and has been hydrogenated. As such mixture of dimer diamine and trimer triamine, there may be listed, for example, the following commercially available products.
Versamine 552 (by Cognis Japan Co., Ltd.), dimer:trimer=95:5, hydrogenated
Priamine-1075 (by Croda Japan K.K.), dimer:trimer=98:2, hydrogenated

The above-listed commercially available products or commercially available products of the mixture of dimer diamine and trimer triamine other than those listed above may undergo a distillation process such as thin film distillation to raise their dimer ratios before use, or the dimer ratio may be adjusted by combining multiple kinds of mixtures of dimer diamine and trimer triamine with different dimer ratios. Further, as for a commercially available product of a non-hydrogenated mixture of dimer diamine and trimer triamine, the mixture may be hydrogenated with the aid of a catalyst such as Raney nickel before use.

As a diamine other than dimer diamine and trimer triamine, commercially available products may be used, examples of which may include various diamines such as the abovementioned aromatic diamine compounds, cyclohexane ring-containing diamine compounds, and aromatic ring- and cyclohexane ring-containing diamine compounds. Any one kind of these diamines may be used alone, or two or more kinds of them may be used in combination, depending on an intended use or the like.

As the cyclic structure-containing tetracarboxylic anhydride, commercially available products may be used, examples of which may include pyromellitic dianhydride, maleic anhydride, succinic anhydride, 4,4′-carbonyldiphthalic anhydride, 4,4′-diphthalic anhydride, 4,4′-sulfonyldiphthalic anhydride, 4,4′-oxydiphthalic anhydride, and 4,4′-(4,4′-isopropylidenediphenoxy)diphthalic anhydride. Any one kind of these acid anhydrides may be used alone, or two or more kinds of them may be used in combination, depending on an intended use or the like. In terms of electric properties of the maleimide compound, preferable acid anhydrides are pyromellitic dianhydride, 4,4′-oxydiphthalic anhydride, and 4,4′-(4,4′-isopropylidenediphenoxy)diphthalic anhydride.

One kind of the component (A) may be used alone, or two or more kinds thereof may be used in a mixed manner.

Further, it is preferred that the component (A) be contained in the curable resin composition of the present invention by an amount of 1 to 99.9% by mass, more preferably 3 to 99% by mass.

Particularly, if using the maleimide compound represented by the formula (1-2), it is preferred that the component (A) be contained in the curable resin composition by an amount of 30 to 99% by mass, more preferably 60 to 95% by mass.

### (B) Catalyst

A component (B) used in the present invention is a catalyst. The catalyst in the present invention is to initiate or promote the cross-linking reaction of the component (A) and/or a reaction between the component (A) and a later-described curable resin having reactive groups capable of reacting with maleimide groups. There are no particular restrictions on such component (B) so long as it is able to initiate or promote the cross-linking reaction of the component (A) and/or the reaction between the component (A) and the later-described curable resin having reactive groups capable of reacting with maleimide groups; it is preferred that there be used at least one selected from an organic peroxide, an anionic polymerization initiator and a photocuring initiator.

Examples of the organic peroxide include dicumyl peroxide, t-butyl peroxybenzoate, t-amyl peroxybenzoate, dibenzoyl peroxide, dilauroyl peroxide, 2,5-dimethyl-2,5-di(t-butylperoxy)hexane, 1,1-di(t-butylperoxy)cyclohexane, di-t-butyl peroxide, and dibenzoyl peroxide.

Examples of the anionic polymerization initiator include imidazole compounds such as imidazole, 2-methylimidazole, 2-ethylimidazole, 2-heptadecylimidazole, 1,2-dimethylimidazole, 2-ethyl-4-methylimidazole, 2-undecylimidazole, 2-phenylimidazole, 2-phenyl-4-methylimidazole, 1-benzyl-2-methylimidazole, 1-cyanoethyl-2-methylimidazole, 1-cyanoethyl-2-ethyl-4-methylimidazole, 1-cyanoethyl-2-undecylimidazole, 1-cyanoethyl-2-phenylimidazole, 2-phenyl-4,5-dihydroxymethylimidazole, and 2-phenyl-4-methyl-5-hydroxymethylimidazole; organic phosphorus compounds such as tributylphosphine, tri(p-methylphenyl)phosphine, tri(nonylphenyl)phosphine, triphenylphosphine, triphenylphosphine oxide, triphenylphosphine-triphenylborane, and tetraphenylphosphine-tetraphenylborate; and tertiary amine compounds such as triethylamine, benzyldimethylamine, α-methylbenzyldimethylamine, 1,8-diazabicyclo[5.4.0]undecene, and tris(dimethylaminomethyl)phenol.

As for the photocuring initiator, there are no particular restrictions imposed thereon so long as it is capable of initiating reactions by light, examples of which may include aromatic ketones such as 2-benzyl-2-dimethylamino-1-(4-morpholinophenyl)-butanone-1,2,2-dimethoxy-1,2-diphenylethan-1-one, 1-hydroxy-cyclohexyl-phenyl-ketone, 2-methyl-1-(4-(methylthio)phenyl)-2-morpholinopropanone-1,2,4-diethylthioxanthone, 2-ethylanthraquinone, and phenanthrenequinone; benzyl derivatives such as benzyl dimethyl ketal; 2,4,5-triarylimidazole dimers such as 2-(o-chlorophenyl)-4,5-diphenylimidazole dimer, 2-(o-chlorophenyl)-4,5-di(m-methoxyphenyl)imidazole dimer, 2-(o-fluorophenyl)-4,5-diphenylimidazole dimer, 2-(o-methoxyphenyl)-4,5-diphenylimidazole dimer, 2-(p-methoxyphenyl)-4,5-diphenylimidazole dimer, 2,4-di(p-methoxyphenyl)-5-phenylimidazole dimer, and 2-(2,4-dimethoxyphenyl)-4,5-diphenylimidazole dimer; acridine derivatives such as 9-phenylacridine and 1,7-bis(9,9′-acridinyl)heptane; bisacylphosphine oxides such as bis(2,6-dimethoxybenzoyl)-2,4,4-trimethyl-pentylphosphine oxide and bis(2,4,6-trimethylbenzoyl)-phenylphosphine oxide; alkylphenone-based compounds such as 1-hydroxy-cyclohexyl-phenyl-ketone, 2-benzyl-2-dimethylamino-1-(4-morpholinophenyl)-butanone-1, and 2-(dimethylamino)-2-[(4-methylphenyl)methyl]-1-[4-(4-morpholinyl)phenyl]-1-butanone; acylphosphine oxide-based compounds such as 2,4,6-trimethylbenzoyl-diphenyl-phosphine oxide; and benzophenone compounds.

It is preferred that the component (B) be added in an amount of 0.1 to 5.0 parts by mass, more preferably 0.2 to 4.5 parts by mass, even more preferably 0.5 to 4.0 parts by mass, per 100 parts by mass of the component (A).

Further, if the composition of the present invention contains a later-described curable resin which is not the component (A) and has reactive groups capable of reacting with maleimide groups, and if a sum total of the component (A) and such curable resin that has reactive groups capable of reacting with maleimide groups is regarded as a curable resin component, it is preferred that the component (B) be added in an amount of 0.1 to 7.0 pars by mass, more preferably 0.2 to 6.0 parts by mass, even more preferably 0.5 to 5.0 parts by mass, per 100 parts by mass of such curable resin component.

The progression of curing may become slow if the component (B) is added in an amount of smaller than 0.1 parts by mass per 100 parts by mass of the component (A); and an impaired preservation stability may be observed if the component (B) is added in an amount of larger than 5.0 parts by mass per 100 parts by mass of the component (A).

One kind of the component (B) may be used alone, or two or more kinds thereof may be used in a mixed manner.

### Other Additives

If necessary, the curable resin composition of the present invention may further contain various additives within the scope of not impairing the effects of the present invention. These additives are exemplified below.

Curable Resin Having Reactive Groups Capable of Reacting with Maleimide Groups

In the present invention, there may further be added a curable resin having reactive groups capable of reacting with maleimide groups.

There are no restrictions on the type of such curable resin, examples of which may include various resins other than the component (A), such as an epoxy resin, a phenolic resin, a melamine resin, a silicone resin, a cyclic imide resin as typified by a maleimide compound other than the component (A), a urea resin, a heat-curable polyimide resin, a modified polyphenylene ether resin, a (meth)acrylic resin, and an epoxy-silicone hybrid resin. Further, examples of the reactive groups capable of reacting with maleimide groups include an epoxy group, a maleimide group, a hydroxyl group, an acid anhydride group, an alkenyl group such as an allyl group and a vinyl group, a (meth)acryloyl group, and a thiol group.

In terms of reactivity, it is preferred that the reactive group in the curable resin be one selected from an epoxy group, a maleimide group, a hydroxyl group and an alkenyl group; and in terms of dielectric property, an alkenyl group or a (meth)acryloyl group are more preferred.

Here, the curable resin having the reactive groups capable of reacting with maleimide groups is added in an amount of 0 to 80% by mass per the sum total of the curable resin component.

### Inorganic Filler

In the present invention, there may further be added an inorganic filler if necessary. An inorganic filler is added to improve the strength and rigidity of the cured product of the curable resin composition of the present invention, or adjust a thermal expansion coefficient and the dimension stability of the cured product. As such inorganic filler, there may be used those that are generally added to an epoxy resin composition or a silicone resin composition. There may be listed, for example, silicas such as a spherical silica, a molten silica and a crystalline silica; alumina; silicon nitride; aluminum nitride; boron nitride; barium sulfate; talc; clay; aluminum hydroxide; magnesium hydroxide; calcium carbonate; glass fibers; and glass particles. Further, for the sake of improving dielectric properties, there may also be used a fluorine-containing resin, a coating filler and/or hollow particles; and for the sake of for example imparting an electric conductivity, there may also be added metal particles, metal-coated inorganic particles, carbon fibers and carbon nanotubes. One kind of such inorganic filler may be used alone, or two or more kinds thereof may be used in combination. The inorganic filler may be added in an amount of 0 to 300 parts by mass, preferably 30 to 300 parts by mass, per 100 parts by mass of the component (A).

There are no particular restrictions on the average particle size and shape of the inorganic filler; if molding a film or a substrate, a spherical silica with an average particle size of 0.5 to 5 μm is particularly preferred. Here, an average particle size is a value obtained as a mass average value D₅₀ (or median size) in a particle size distribution measurement conducted by a laser diffraction method.

Further, for the sake of property improvement, it is preferred that the inorganic filler be one that has already been surface-treated with a silane coupling agent having organic groups capable of reacting with maleimide groups. Examples of such silane coupling agent include an epoxy group-containing alkoxysilane, an amino group-containing alkoxysilane, a (meth)acryloyl group-containing alkoxysilane, and an alkenyl group-containing alkoxysilane.

As such silane coupling agent, preferred are a (meth)acryloyl group- and/or an amino group-containing alkoxysilane, specific examples of which include 3-methacryloxypropyltrimethoxysilane, 3-acryloxypropyltrimethoxysilane, N-phenyl-3-aminopropyltrimethoxysilane, N-2-(aminoethyl)-3-aminopropyltrimethoxysilane, and 3-aminopropyltrimethoxysilane.

### Others

In addition to the above additives, there may also be added, for example, a non-functional silicone oil, a reactive diluent, a thermoplastic resin, a thermoplastic elastomer, an organic synthetic rubber, a photosensitizer, a light stabilizer, a polymerization inhibitor, an antioxidant, a flame retardant, a pigment, a dye, an adhesion aid and an ion-trapping agent.

Further, the above silane coupling agents such as an epoxy group-containing alkoxysilane, an amino group-containing alkoxysilane, a (meth)acryloyl group-containing alkoxysilane and an alkenyl group-containing alkoxysilane that are used for surface-treating the inorganic filler, may be separately added to the curable resin composition of the present invention, and specific examples thereof may be ones that are similar to those listed above.

The curable resin composition of the present invention may also be handled as a varnish after being dissolved into an organic solvent. By turning the composition into a varnish, a film can be formed easily, and a fiber base material such as a glass cloth made of an E glass, a low-dielectric glass, a quartz glass or the like can be easily coated and impregnated therewith. There are no restrictions on the organic solvent so long as it is capable of dissolving the components (A) and (B) as well as the curable resin, as one of the other additives, that has reactive groups capable of reacting with maleimide groups; there may be listed, for example, anisole, tetralin, mesitylene, xylene, toluene, tetrahydrofuran (THF), dimethylformamide (DMF), dimethyl sulfoxide (DMSO), and acetonitrile. Any one kind of them may be used alone, or two or more kinds thereof may be used in combination.

### Production Method

As a method for producing the curable resin composition of the present invention, there may be employed, for example, a method where the components (A) and (B) as well as other additives that are added if necessary are to be mixed using a planetary mixer (by INOUE MFG., INC.) or a mixer “THINKY CONDITIONING MIXER” (by THINKY CORPORATION).

In the present invention, if using the maleimide compound represented by the formula (1-1) as the component (A), particularly, since the maleimide compound serving as a base resin in the composition has a low viscosity, the composition shall have an excellent workability and flow property, and the cured product thereof shall exhibit excellent dielectric properties both at high frequencies and after being left under a high temperature for a long period of time, and a small susceptibility to moisture absorption.

In the present invention, if using the maleimide compound represented by the formula (1-2) as the component (A), particularly, the cured product of the composition will exhibit a small warpage due to its low elasticity and low hardness after curing, an excellent crack resistance, excellent dielectric properties even at high frequencies, and therefore small changes in dielectric properties even after being left under a high temperature for a long period of time.

It is preferred that the cured product of the composition using the maleimide compound represented by the formula (1-2) as the component (A) have a storage elastic modulus of smaller than 1,000 MPa, more preferably not larger than 900 MPa, even more preferably not larger than 800 MPa, at 25° C. A storage elastic modulus of not smaller than 1,000 MPa may lead to a larger warpage after curing if the composition is used as an adhesive or a film.

Here, the storage elastic modulus is a value measured by a method described in JIS K7244-4:1999 and by a dynamic mechanical analyzer such as DMA-Q800 (by TA Instruments) at a frequency of 10 Hz and a temperature rising rate of 5° C./min in a temperature range of −50 to 200° C.

In order to improve the crack resistance of the cured product of the composition using the maleimide compound represented by the formula (1-2) as the component (A), it is preferred that the cured product have a hardness of not higher than D50, more preferably not higher than D40, even more preferably not higher than D30, at 25° C. A hardness of higher than D50 may lead to a poor crack resistance if the composition is used as a semiconductor encapsulation material. Here, the hardness is a value measured in accordance with a method described in JIS K 6253-3:2012, using a type D durometer where the measurement is conducted at a measurement temperature of 25° C.

In the present invention, if using the maleimide compound represented by the formula (1-3) as the component (A), there can be obtained a cured product having excellent dielectric properties (low relative permittivity, low dielectric tangent, low frequency dependency, high heat resistance) and a high adhesion force to a metal such as copper, while having a high Tg and a low CTE.

The glass-transition temperature (Tg) of the composition using the maleimide compound represented by the formula (1-3) as the component (A) is preferably higher than 120° C., more preferably 130° C. or higher, when measured by dynamic mechanical analysis (DMA) after curing. A high Tg leads to an improved dimension stability of the cured product. Further, a compound with a high Tg exhibits a low linear coefficient of expansion (low CTE) in most cases, this aspect shall be effective in improving dimension stability as well.

### Uncured Resin Film/Cured Resin Film

As for the curable resin composition of the present invention, an uncured resin sheet or an uncured resin film can be obtained by applying the varnish to a base material and then volatilizing the organic solvent, and a cured resin sheet or a cured resin film can be obtained by further curing the uncured resin sheet or film. Examples of a method for producing the sheet and film include, but are not limited to those described below.

For example, after applying to a base material the curable resin composition dissolved in the organic solvent (i.e. varnish), the organic solvent is eliminated by performing heating at a temperature of normally not lower than 80° C., preferably not lower than 100° C. for 0.5 to 20 min, and a strong cured resin film with a flat surface can then be formed by further performing heating at a temperature of not lower than 130° C., preferably not lower than 150° C. for 0.5 to 10 hours.

The temperature in the drying step for eliminating the organic solvent and the temperature in the subsequent heating and curing step may each be a constant temperature; it is preferred that these temperatures be raised in a step-wise manner. Thus, not only the organic solvent can be efficiently eliminated out of the composition, but the curing reaction of the resins can also take place efficiently.

Examples of a method for applying the varnish may include those employing a spin coater, a slit coater, a sprayer, a dip coater and a bar coater; there are no particular restrictions on such method.

As a base material, there may be used a general resin base material, examples of which include polyolefin resins such as a polyethylene (PE) resin, a polypropylene (PP) resin and a polystyrene (PS) resin; and polyester resins such as a polyethylene terephthalate (PET) resin, a polybutylene terephthalate (PBT) resin and a polycarbonate (PC) resin. The surface of such base material may also be subjected to a mold release treatment. Further, there are no particular restrictions on the thickness of a coating layer; a thickness after distilling away the solvent is 1 to 100 μm, preferably 3 to 80 μm. A cover film may also be provided on such coating layer.

Instead, the uncured resin film or cured resin film may also be produced by previously and preliminarily mixing the components, and then extruding the mixture into the shape of a sheet or a film with a melt-kneading machine.

The cured film obtained by curing the curable resin composition of the present invention is not only superior in heat resistance, mechanical properties, electric properties, adhesiveness to base materials and solvent resistance, but also has a low relative permittivity. Thus, the composition of the invention can be applied to, for example, a passivation film or protective film for use in a semiconductor device, specifically those provided on the surface of a semiconductor element; a junction protective film for use in the junctions of a diode, a transistor or the like; an α-ray shielding film or interlayer insulating film for use in a VLSI; and an ion implantation mask. Moreover, the composition of the invention may also be applied to a conformal coating of a printed-circuit board, an oriented film of a liquid crystal surface element, a protective film of glass fibers, and a surface protective film of a solar cell. Further, the composition of the invention may be applied to a wide range of uses such as a paste composition including, for example, a paste composition for printing with an inorganic filler being added to the above curable resin composition, and an electrically conductive paste composition with an electrically conductive filler being added to such resin composition. Particularly, a use as an adhesive is preferred.

Further, since the composition of the present invention can be turned into the shape of a film or a sheet in an uncured state, has a self-adhesiveness and is also superior in dielectric properties, the film of such composition is particularly suitable for use as, for example, a bonding film or adhesive film used in a flexible printed-wiring circuit board (FPC) or the like, and an interlayer insulating material of a rigid substrate. Further, the cured resin film may also be used as a coverlay film.

Instead, a fiber base material such as a glass cloth made of an E glass, a low-dielectric glass, a quartz glass or the like may be impregnated with the curable resin composition that has been turned into a varnish, followed by eliminating the organic solvent to achieve a semi-cured state, thereby allowing the product thus obtained to be used as a prepreg. Further, a laminate or printed-wiring board including multilayered ones can be produced by laminating such prepreg and a copper foil or the like.

### Prepreg

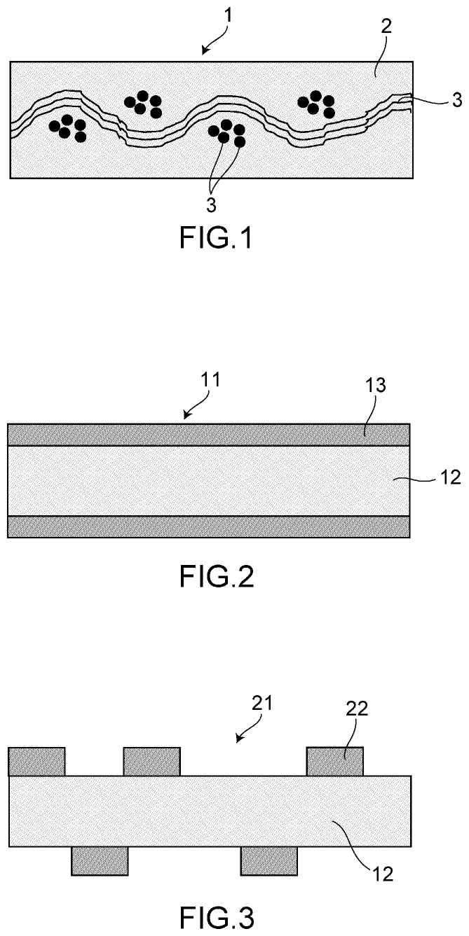

FIG. 1 schematically shows an end surface of a prepreg of one embodiment of the present invention. A prepreg 1 has a curable resin composition 2 and a fiber base material 3. The curable resin composition 2 is ether the above curable resin composition or a semi-cured product of such resin composition.

Here, a semi-cured product refers to a product of a state where the resin composition has been incompletely cured to the extent that the composition can actually be further cured. That is, the semi-cured product is a product of a state where the resin composition has been semi-cured i.e. a B-staged product. Meanwhile, an uncured state may also be referred to as A-stage.

That is, the curable resin composition 2 may be the curable resin composition in the state of A-stage, or the curable resin composition in the state of B-stage.

As described above, the fiber base material 3 may for example be an E glass, a low-dielectric glass, a quartz glass, or even an S glass or T glass; while there may be employed any type of glass, a quartz glass cloth having low dielectric properties is preferred in terms of taking advantage of the properties of a curable resin composition. Here, the thickness of a generally used fiber base material is, for example, not smaller than 0.01 mm and not larger than 0.3 mm.

When producing the prepreg 1, it is preferred that the curable resin composition 2 be a resin varnish prepared in the form of a varnish, because the fiber base material 3 as a base material for forming the prepreg is to be impregnated with the resin composition. Such resin composition in the form of a varnish (i.e. resin varnish) may for example be prepared as follows.

At first, components in the composition of the resin composition that are soluble in the organic solvent are to be added to the organic solvent to dissolve them. At that time, heating may also be performed if necessary. Next, components that are insoluble in the organic solvent, such as the inorganic filler used as needed are added, followed by using a ball mill, a bead mill, a planetary mixer, a roll mill or the like to disperse them until a given dispersed state has been reached, thereby obtaining the resin composition in the form of a varnish (i.e. resin varnish). There are no particular restrictions on the organic solvent used here so long as the organic solvent employed does not inhibit the curing reaction. Specific examples thereof include toluene, methyl ethyl ketone (MEK), xylene and anisole.

As a method for producing the prepreg 1, there may be employed, for example, a method where the fiber base material 3 is at first impregnated with the curable resin composition 2 e.g. the curable resin composition 2 prepared in the form of a varnish, and is then dried. The fiber base material 3 is to be impregnated with the curable resin composition 2 by, for example, dipping the fiber base material 3 into the resin composition, or applying the resin composition to the fiber base material 3. If necessary, the fiber base material 3 may be repeatedly impregnated several times. Further, at that time, it is also possible to repeat impregnation using multiple resin compositions with different compositions and concentrations, whereby the composition and impregnation amount can eventually be adjusted to desired ones. The fiber base material 3 impregnated with the curable resin composition (resin varnish) 2 is to be heated under a desired heating condition(s) e.g. at 80 to 180° C. for 1 to 20 min. By heating, there can be obtained a prepreg 1 having an uncured (A-staged) or semi-cured (B-staged) curable resin composition 2. Here, heating performed in the above manner will volatilize the organic solvent from the resin varnish whereby the organic solvent will be able to be reduced or eliminated.

### Laminate

A laminate of one embodiment of the present invention is one prepared by laminating an insulating layer containing or consisting of the cured product of the curable resin composition; and a layer other than the insulating layer. A generally well-known laminate is a metal-clad laminate; FIG. 2 schematically shows an end surface thereof. A metal-clad laminate 11 has an insulating layer 12 containing or consisting of the cured product of the curable resin composition; and a metal foil 13 arranged on both surfaces of the insulating layer 12. Shown in FIG. 2 is a double-sided metal-clad laminate with the metal foil 13 being provided on both surfaces of the insulating layer 12; the metal-clad laminate may also be a single-sided metal-clad laminate with the metal foil 13 being provided only on one surface of the insulating layer 12.

Further, the insulating layer 12 may be a layer consisting of the cured product of the curable resin composition, a layer consisting of the cured product of the prepreg 1, or even a layer with multiple pieces of the cured product of the prepreg 1 being laminated together. Further, there are no particular restrictions on the thickness of the metal foil 13; this thickness varies depending on, for example, the performance required for a wiring board that is eventually manufactured. The thickness of the metal foil 13 may be appropriately determined depending on a desired purpose; for example, a thickness of 1 to 70 μm is preferred. Further, the metal foil 13 may for example be a copper foil, an aluminum foil or the like; if the metal foil is thin, there may be employed a carrier-attached copper foil having a release layer and a carrier, for the purpose of improving handling property.

There are no particular restrictions on a method for producing such laminate so long as the method used is a general method. For example, if using the prepreg, there may be employed a method where the laminate is produced in such a manner that one or multiple pieces of the prepreg 1 (FIG. 1) are to be stacked together, and the metal foil 13 such as a copper foil is then placed on one or both surfaces thereof in the vertical direction before performing heating and pressurization so as to mold them into an integrally laminated product.

### Printed-Wiring Board

A printed-wiring board of one embodiment of the present invention is one containing the cured product of the curable resin composition; as one example thereof, FIG. 3 schematically shows an end surface of a printed-wiring board produced using the abovementioned laminate, particularly the metal-clad laminate shown in FIG. 2. As described above, the insulating layer 12 of the metal-clad laminate used in the production of a printed-wiring board may be one produced using the aforementioned prepreg. By known methods, a printed-wiring board 21 can be produced by performing a drilling processing, a metal plating processing, a circuit formation processing and a multilayer adhesion processing, of which the circuit formation processing is realized by performing etching or the like on the metal foil.

### Semiconductor Encapsulation Material

If using the curable resin composition of the present invention as a semiconductor encapsulation material, the components (A) and (B) as well as other components, if needed, may be combined at given compounding ratios, and a mixer or the like may then be used to sufficiently uniformly mix them, after which the components may be melt-mixed using a heated roller, a kneader, an extruder or the like, followed by cooling the mixture so as to solidify the same before crushing it into an appropriate size(s). The resin composition obtained can be used as an encapsulation material.

As a general molding method for a semiconductor encapsulation material, there may be employed, for example, a transfer molding method or a compression molding method. In a transfer molding method, a transfer molding machine is used, where at a molding pressure of 5 to 20 N/mm², molding is carried out at a molding temperature of 120 to 190° C. for a molding time of 30 to 500 sec, preferably at a molding temperature of 150 to 185° C. for a molding time of 30 to 180 sec. Further, in a compression molding method, a compression molding machine is used, where molding is carried out at a molding temperature of 120 to 190° C. for a molding time of 30 to 600 sec, preferably at a molding temperature of 130 to 160° C. for a molding time of 120 to 300 sec. Furthermore, in either molding method, post curing may be performed at 150 to 225° C. for 0.5 to 20 hours.

### Working Examples

The present invention is described in detail hereunder with reference to working and comparative examples; the present invention shall not be limited to the following working examples.

The components used in the working and comparative examples are shown below. Here, the number average molecular weight (Mn) mentioned hereunder is measured under the following measurement conditions, using polystyrene as a reference substance.

### Measurement Conditions

Developing solvent: Tetrahydrofuran (THF)
Flow rate: 0.35 mL/min
Detector: Differential refractive index detector (RI)
Column: TSK Guardcolumn Super H-L
   TSK gel Super HZ4000 (4.6 mm I.D.×15 cm×1)
   TSK gel Super HZ3000 (4.6 mm I.D.×15 cm×1)
   TSK gel Super HZ2000 (4.6 mm I.D.×15 cm×2)
(All manufactured by Tosoh Corporation)
Column temperature: 40° C.
Sample injection volume: 5 μL (THF solution with a concentration of 0.2% by mass)

Further, the dimer ratio (mass ratio of dimer:trimer) was calculated from a peak area ratio in a gas chromatography (GC) measurement conducted under the following measurement conditions.

### Measurement Conditions

Device: GC-2014 (by SHIMADZU CORPORATION)
Column: DB-5 30 m×0.25 mm×0.25 μm
Gasification chamber temperature: 280° C.
Temperature: 50° C.→10° C./min→300° C., maintained for 20 min
Column flow rate: 1.00 mL/min
Purge flow rate: 3.00 mL/min

### Example 1. Composition Using Component (A) Represented by Formula (1-1)

### Amine Compound

In the synthesis examples, there were used amine compounds obtained by the following operations, or commercially available amine compounds.

### Amine Compound 1-1

Priamine-1075 (by Croda Japan K.K., hydrogenated, dimer:trimer≈98:2)

### Amine Compound 2-1

Priamine-1074 (by Croda Japan K.K., hydrogenated, dimer:trimer≈95:5)

### Amine Compound 3-1

An amine compound 3-1 was obtained by subjecting 300 g of Priamine-1075 to thin film distillation at 200° C. for 60 min. The main chain of the amine compound 3-1 was hydrogenated, and the dimer ratio was dimer:trimer≈99.2:0.8.

### Amine Compound 4-1

An amine compound 4-1 was obtained by mixing 80.25 g of Priamine-1075 and 160.50 g of Priamine-1074. The main chain of the amine compound 4-1 was hydrogenated, and the dimer ratio was dimer:trimer≈96:4.

### Amine Compound 5-1

An amine compound 5-1 was obtained by mixing 160.50 g of Priamine-1075 and 80.25 g of Priamine-1074. The main chain of the amine compound 5-1 was hydrogenated, and the dimer ratio was dimer:trimer≈97:3.

### Amine Compound 6-1

An amine compound 6-1 was obtained by subjecting 300 g of Priamine-1075 to thin film distillation at 200° C. for 45 min. The main chain of the amine compound 6-1 was hydrogenated, and the dimer ratio was dimer:trimer≈99.0:1.0.

### Amine Compound 7-1 (for Use in Comparative Example)

Priamine-1073 (by Croda Japan K.K., non-hydrogenated, dimer:trimer≈95:5)

### Amine Compound 8-1 (for Use in Comparative Example)

Priamine-1071 (by Croda Japan K.K., non-hydrogenated, dimer:trimer≈80:20)

### Amine Compound 9-1 (for Use in Comparative Example)

An amine compound 9-1 was obtained by subjecting 300 g of Priamine-1071 to thin film distillation at 180° C. for 60 min, and then performing hydrogenation with Raney nickel. The main chain of the amine compound 9-1 was hydrogenated, and the dimer ratio was dimer:trimer≈93:7.

### Amine Compound 10-1 (for Use in Comparative Example)

An amine compound 10-1 was obtained by subjecting 300 g of Priamine-1071 to thin film distillation at 180° C. for 45 min, and then performing hydrogenation with Raney nickel. The main chain of the amine compound 10-1 was hydrogenated, and the dimer ratio was dimer:trimer≈90:10.

### (A) Maleimide Compound

Maleimide compounds were synthesized by the following operations using the above listed amine compounds as raw materials. Here, the maleimide compound obtained in each synthesis example was such that the group D in the formula (1) was a dimer acid- and trimer acid-derived hydrocarbon group, had the dimer ratio shown in Table 1, and was either hydrogenated or non-hydrogenated as indicated in Table 1.

### Synthesis Example 1-1

An amic acid was synthesized by adding 240.75 g (0.45 mol) of the amine compound 1-1, 97.2 g (0.99 mol) of maleic anhydride and 150 g of toluene into a 1 L glass four-necked flask equipped with a stirrer, a Dean-Stark apparatus, a cooling condenser and a thermometer, and then stirring them at 80° C. for 3 hours. Next, after adding 40 g of methanesulfonic acid, the temperature was raised to 110° C., where stirring was performed for 24 hours while distilling away water produced as a by-product, after which the reaction solution was washed 5 times with 200 g of an ion-exchange water. Next, stripping was performed at 60° C. under a reduced pressure to obtain 297.1 g (yield 95%, Mn 1,050) of a target substance (A-1-1) as a brown liquid at room temperature.

### Synthesis Example 2-1

Here, 297.0 g (yield 95%, Mn 1,130) of a target substance (A-2-1) as a brown liquid was obtained by performing similar operations, except that the amine compound 1-1 of the synthesis example 1-1 was changed to an equimolar amount of the amine compound 2-1.

### Synthesis Example 3-1

Here, 296.0 g (yield 94%, Mn 1,010) of a target substance (A-3-1) as a brown liquid was obtained by performing similar operations, except that the amine compound 1-1 of the synthesis example 1-1 was changed to an equimolar amount of the amine compound 3-1.

### Synthesis Example 4-1

Here, 297.1 g (yield 95%, Mn 1,130) of a target substance (A-4-1) as a brown liquid was obtained by performing similar operations, except that the 240.75 g of the amine compound 1-1 of the synthesis example 1-1 was changed to 240.75 g of the amine compound 4-1.

### Synthesis Example 5-1

Here, 296.7 g (yield 95%, Mn 1,090) of a target substance (A-5-1) as a brown liquid was obtained by performing similar operations, except that the 240.75 g of the amine compound 1-1 of the synthesis example 1-1 was changed to 240.75 g of the amine compound 5-1.

### Synthesis Example 6-1

Here, 296.0 g (yield 94%, Mn 1,010) of a target substance (A-6-1) as a brown liquid was obtained by performing similar operations, except that the amine compound 1-1 of the synthesis example 1-1 was changed to an equimolar amount of the amine compound 6-1.

### Synthesis Example 7-1

Here, 294.0 g (yield 94%, Mn 1,160, for use in comparative example) of a target substance (A-7-1) as a brown liquid was obtained by performing similar operations, except that the amine compound 1-1 of the synthesis example 1-1 was changed to an equimolar amount of the amine compound 7-1.

### Synthesis Example 8-1

Here, 290.8 g (yield 93%, Mn 1,380, for use in comparative example) of a target substance (A-8-1) as a brown liquid was obtained by performing similar operations, except that the amine compound 1-1 of the synthesis example 1-1 was changed to an equimolar amount of the amine compound 8-1.

### Synthesis Example 9-1

Here, 291.0 g (yield 93%, Mn 1,200, for use in comparative example) of a target substance (A-9-1) as a brown liquid was obtained by performing similar operations, except that the amine compound 1-1 of the synthesis example 1-1 was changed to an equimolar amount of the amine compound 9-1.

### Synthesis Example 10-1

Here, 291.0 g (yield 93%, Mn 1,220, for use in comparative example) of a target substance (A-10-1) as a brown liquid was obtained by performing similar operations, except that the amine compound 1-1 of the synthesis example 1-1 was changed to an equimolar amount of the amine compound 10-1.

### Viscosity

The viscosity of each maleimide compound synthesized was measured by the method described in JIS Z8803:2011 and by a Brookfield-type rotary viscometer at a measurement temperature of 25° C. and a spindle rotation speed of 5 rpm. The results thereof are shown in Table 1.

### (B) Catalyst

### (B-1-1): 2,5-dimethyl-2,5-di(t-butylperoxy)hexane (Trigonox 101 by KAYAKU NOURYON CORPORATION)

### Sample Preparation

The components were put into a plastic container at the compounding ratios shown in Table 2, and a THINKY mixer (Awatori Rentaro ARE-310 by THINKY CORPORATION) was then used to mix them so as to obtain each resin composition.

Dielectric property and heat resistance There was used a frame having a size of 70 mm×70 mm and a thickness of 200 μm. Each resin composition was sandwiched by two pieces of a PET film that had been subjected to a mold release treatment and had a thickness of 50 μm (E7006 by TOYOBO CO., LTD.), and a vacuum press machine (by Nikko-Materials Co., Ltd.) was then used to perform molding at 160° C. for 5 min, thereby obtaining a cured product (molded film). After obtaining a cured resin film by post-curing the molded film at 180° C. for 1 hour, a network analyzer (E5063-2D5 by Keysight Technologies) and a stripline (by KEYCOM Corporation) were connected using the cured resin film to measure a relative permittivity and dielectric tangent thereof at frequencies of 10 GHz and 28 GHz.

Further, the relative permittivity and dielectric tangent of this cured resin film were likewise measured at the frequencies of 10 GHz and 28 GHz after leaving the same at 150° C. for 48 hours.

### Moisture Absorbency

There was used a mold having a size of 15 mm×5 mm and a thickness of 5 mm. Each resin composition was sandwiched by two pieces of a PET film that had been subjected to a mold release treatment and had a thickness of 50 μm (E7006 by TOYOBO CO., LTD.), and a vacuum press machine (by Nikko-Materials Co., Ltd.) was then used to perform molding at 160° C. for 5 min, thereby obtaining a cured product. The cured product was post-cured at 180° C. for 1 hour, and the weight of this cured product was then measured. Next, the weight of the cured product was again measured after leaving the same in a thermostatic bath of 85° C., 85% for 24 hours, and a rate of increase in weight after absorbing moisture was calculated as a moisture absorbency (%).

TABLE 1

| Maleimide compound | | A-1-1 | A-2-1 | A-3-1 | A-4-1 | A-5-1 | A-6-1 | A-7-1 | A-8-1 | A-9-1 | A-10-1 |
|---|---|---|---|---|---|---|---|---|---|---|---|
| Dimer:Trimer | (Mass ratio) | 98:2 | 95:5 | 99.2:0.8 | 96:4 | 97:3 | 99:1 | 95:5 | 80:20 | 93:7 | 90:10 |
| Hydrogenation | | Hydro- | Hydro- | Hydro- | Hydro- | Hydro- | Hydro- | Non-hydro- | Non-hydro- | Hydro- | Hydro- |
| treatment | | genated | genated | genated | genated | genated | genated | genated | genated | genated | genated |
| Viscosity | Pa · s | 3.5 | 6.5 | 3.3 | 4.8 | 4.0 | 3.3 | 9.1 | 13.4 | 7.2 | 8.5 |

Maleimide compounds (A) having a group that had a dimer ratio of 95% by mass or more and was hydrogenated each exhibited a low viscosity of 7.0 Pa s or lower when measured at 25° C. under the above conditions.

TABLE 2

| Composition table | | Working example | | | | | | Comparative example | | | |
|---|---|---|---|---|---|---|---|---|---|---|---|
| (part by mass) | | 1-1 | 2-1 | 3-1 | 4-1 | 5-1 | 6-1 | 1-1 | 2-1 | 3-1 | 4-1 |
| (A)Component | A-1-1 | 100.0 | | | | | | | | | |
| | A-2-1 | | 100.0 | | | | | | | | |
| | A-3-1 | | | 100.0 | | | | | | | |
| | A-4-1 | | | | 100.0 | | | | | | |
| | A-5-1 | | | | | 100.0 | | | | | |
| | A-6-1 | | | | | | 100.0 | | | | |
| | A-7-1 | | | | | | | 100.0 | | | |
| | A-8-1 | | | | | | | | 100.0 | | |
| | A-9-1 | | | | | | | | | 100.0 | |
| | A-10-1 | | | | | | | | | | 100.0 |
| (B)Component | B-1-1 | 2.0 | 2.0 | 2.0 | 2.0 | 2.0 | 2.0 | 2.0 | 2.0 | 2.0 | 2.0 |
| Relative permit- | (Initial) | 2.41 | 2.42 | 2.40 | 2.41 | 2.41 | 2.40 | 2.42 | 2.41 | 2.42 | 2.42 |
| tivity at 10 GHz | | | | | | | | | | | |
| Relative permit- | (After heat | 2.42 | 2.44 | 2.40 | 2.43 | 2.43 | 2.40 | 2.46 | 2.42 | 2.44 | 2.46 |
| tivity at 10 GHz | treatment) | | | | | | | | | | |
| Relative permit- | (Initial) | 2.39 | 2.41 | 2.38 | 2.39 | 2.39 | 2.38 | 2.41 | 2.39 | 2.41 | 2.40 |
| tivity at 28 GHz | | | | | | | | | | | |
| Relative permit- | (After heat | 2.39 | 2.43 | 2.38 | 2.40 | 2.40 | 2.38 | 2.45 | 2.39 | 2.43 | 2.43 |
| tivity at 28 GHz | treatment) | | | | | | | | | | |
| Dielectric tangent | (Initial) | 0.0017 | 0.0017 | 0.0017 | 0.0017 | 0.0017 | 0.0017 | 0.0016 | 0.0023 | 0.0018 | 0.0020 |
| at 10 GHz | | | | | | | | | | | |
| Dielectric tangent | (After heat | 0.0024 | 0.0026 | 0.0022 | 0.0025 | 0.0024 | 0.0022 | 0.0030 | 0.0045 | 0.0033 | 0.0035 |
| at 10 GHz | treatment) | | | | | | | | | | |
| Dielectric tangent | (Initial) | 0.0016 | 0.0018 | 0.0016 | 0.0017 | 0.0017 | 0.0016 | 0.0017 | 0.0026 | 0.0018 | 0.0018 |
| at 28 GHz | | | | | | | | | | | |
| Dielectric tangent | (After heat | 0.0022 | 0.0025 | 0.0021 | 0.0024 | 0.0022 | 0.0021 | 0.0029 | 0.0048 | 0.0030 | 0.0033 |
| at 28 GHZ | treatment) | | | | | | | | | | |
| Moisture | % | 0.28 | 0.35 | 0.25 | 0.35 | 0.33 | 0.25 | 0.34 | 0.48 | 0.36 | 0.41 |
| absorbency | | | | | | | | | | | |

As for the compositions of the working examples that contained a maleimide compound (A) having a group that had a dimer ratio of 95% by mass or more and was hydrogenated, an excellent workability was exhibited, and there were exhibited excellent dielectric properties in a way such that the cured compositions each exhibited a low relative permittivity and dielectric tangent even at a high frequency of, for example, 10 to 28 GHz, and that there were only observed small changes in relative permittivity and dielectric tangent even after storing the cured product of the composition under a high temperature for a long period of time, as compared to before the storage. Further, the cured product of the composition in each working example exhibited a low moisture absorbency, which indicated that the cured product in each working example was less susceptible to moisture absorption.

In contrast, as for the cured product obtained in the comparative example 1-1 where the composition contained a maleimide compound having a group that had a dimer ratio of 95% by mass or more but was not hydrogenated, a larger value of dielectric tangent was observed particularly after the heat treatment, which indicated that the cured product of this composition would exhibit deteriorated dielectric properties if stored under a high temperature. Further, as for the cured products obtained in the comparative examples 2-1 to 4-1 where the compositions each contained a maleimide compound having a dimer ratio of less than 95% by mass, large values of dielectric tangent were observed after the heat treatment, and large values of moisture absorbency were confirmed as well.

### Example 2. Composition Using Component (A) Represented by Formula (1-2)

### Amine Compound

In the synthesis examples, there were used amine compounds obtained by the following operations, or commercially available amine compounds.

### Amine Compound 1-2

Priamine-1075 (by Croda Japan K.K., hydrogenated, dimer:trimer≈98:2)

### Amine Compound 2-2

Priamine-1074 (by Croda Japan K.K., hydrogenated, dimer:trimer≈95:5)

### Amine Compound 3-2

An amine compound 3-2 was obtained by subjecting 300 g of Priamine-1075 to thin film distillation at 200° C. for 60 min. The main chain of the amine compound 3-2 was hydrogenated, and the dimer ratio was dimer:trimer≈99.2:0.8.

### Amine Compound 4-2

An amine compound 4-2 was obtained by mixing 80 g of Priamine-1075 and 161 g of Priamine-1074. The main chain of the amine compound 4-2 was hydrogenated, and the dimer ratio was dimer:trimer≈96:4.

### Amine Compound 1′-2 (for Use in Comparative Example)

Priamine-1073 (by Croda Japan K.K., non-hydrogenated, dimer:trimer≈95:5)

### Amine Compound 2′-2 (for Use in Comparative Example)

Priamine-1071 (by Croda Japan K.K., non-hydrogenated, dimer:trimer≈80:20)

### Amine Compound 3′-2 (for Use in Comparative Example)

An amine compound 3′-2 was obtained by subjecting 300 g of Priamine-1071 to thin film distillation at 180° C. for 60 min, and then performing hydrogenation with Raney nickel. The main chain of the amine compound 3′-2 was hydrogenated, and the dimer ratio was dimer:trimer≈93:7.

### (A) Maleimide Compound

Maleimide compounds were synthesized by the following operations using the above listed amine compounds as raw materials. Here, the maleimide compound obtained in each synthesis example was such that the group D in the formula (1) was a dimer acid- and trimer acid-derived hydrocarbon group, had the dimer ratio shown in Table 3, and was either hydrogenated or non-hydrogenated as indicated in Table 3. A in the formula (1) was a tetravalent organic group having a cyclic structure derived from the tetracarboxylic anhydride in each synthesis example.

### Synthesis Example 1-2

Here, 241 g (0.45 mol) of the amine compound 1-2, 87 g (0.4 mol) of pyromellitic dianhydride, 20 g of methanesulfonic acid and 300 g of toluene were added into a 1 L glass four-necked flask equipped with a stirrer, a Dean-Stark apparatus, a cooling condenser and a thermometer. There, the temperature was raised to 110° C., where stirring was performed for 24 hours while distilling away water produced as a by-product. After the reaction was over, 97 g (0.99 mol) of maleic anhydride was added, and stirring was performed at 110° C. for 6 hours while distilling away water produced as a by-product, after which the reaction solution was washed 5 times with 200 g of an ion-exchange water. Next, hexane was used to perform reprecipitation to obtain 300 g (yield 90%, Mn=5,000, n=7 in the formula (1)) of a target substance (A-1-2) as a yellow solid.

### Synthesis Example 2-2

Here, 428 g (0.8 mol) of the amine compound 1-2, 186 g (0.6 mol) of 4,4′-oxydiphthalic anhydride, 20 g of methanesulfonic acid and 200 g of toluene were added into a 1 L glass four-necked flask equipped with a stirrer, a Dean-Stark apparatus, a cooling condenser and a thermometer. There, the temperature was raised to 110° C., where stirring was performed for 24 hours while distilling away water produced as a by-product. After the reaction was over, 97.2 g (0.99 mol) of maleic anhydride was added, and stirring was performed at 110° C. for 6 hours while distilling away water produced as a by-product, after which the reaction solution was washed 5 times with 200 g of an ion-exchange water. Next, stripping was performed at 80° C. under a reduced pressure to obtain 540 g (yield 87%, Mn=3,000, n=3 in the formula (1)) of a target substance (A-2-2) as a brown solid at room temperature.

### Synthesis Example 3-2

Here, 290 g (yield 88%, Mn=5,300, n=7 in the formula (1)) of a target substance (A-3-2) as a yellow solid was obtained by performing similar operations, except that the amine compound 1-2 of the synthesis example 1-2 was changed to an equimolar amount of the amine compound 2-2.

### Synthesis Example 4-2

Here, 280 g (yield 85%, Mn=4,500, n=6 in the formula (1)) of a target substance (A-4-2) as a yellow solid was obtained by performing similar operations, except that the amine compound 1-2 of the synthesis example 1-2 was changed to an equimolar amount of the amine compound 3-2.

### Synthesis Example 5-2

Here, 290 g (yield 88%, Mn=5,000, n=7 in the formula (1)) of a target substance (A-5-2) as a yellow solid was obtained by performing similar operations, except that the 241 g of the amine compound 1-2 of the synthesis example 1-2 was changed to 241 g of the amine compound 4-2.

### Synthesis Example 6-2

Here, 530 g (yield 86%, Mn=3,000, n=3 in the formula (1)) of a target substance (A-6-2) as a brown solid was obtained by performing similar operations, except that the amine compound 1-2 of the synthesis example 2-2 was changed to an equimolar amount of the amine compound 3-2.

### Comparative Synthesis Example 1-2

Here, 290 g (yield 88%, Mn=6,000, n=8 in the formula (1), for use in comparative example) of a target substance (A′-1-2) as a yellow solid was obtained by performing similar operations, except that the amine compound 1-2 of the synthesis example 1-2 was changed to an equimolar amount of the amine compound 1′-2.

### Comparative Synthesis Example 2-2

Here, 300 g (yield 90%, Mn=7,000, n=9 in the formula (1), for use in comparative example) of a target substance (A′-2-2) as a yellow solid was obtained by performing similar operations, except that the amine compound 1-2 of the synthesis example 1-2 was changed to an equimolar amount of the amine compound 2′-2.

### Comparative Synthesis Example 3-2

Here, 290 g (yield 88%, Mn=7,000, n=9 in the formula (1), for use in comparative example) of a target substance (A′-3-2) as a yellow solid was obtained by performing similar operations, except that the amine compound 1-2 of the synthesis example 1-2 was changed to an equimolar amount of the amine compound 3′-2.

### Comparative Synthesis Example 4-2

Here, 530 g (yield 86%, Mn=4,000, n=4 in the formula (1), for use in comparative example) of a target substance (A′-4-2) as a brown solid was obtained by performing similar operations, except that the amine compound 1-2 of the synthesis example 2-2 was changed to an equimolar amount of the amine compound 2′-2.

### (B) Catalyst

### (B-1-2): 2,5-dimethyl-2,5-di(t-butylperoxy)hexane (Trigonox 101 by KAYAKU NOURYON CORPORATION)

### Sample Preparation

The components were put into a plastic container at the compounding ratios shown in Tables 4-1 and 4-2, and a THINKY mixer (Awatori Rentaro ARE-310 by THINKY CORPORATION) was then used to mix them so as to obtain each resin composition.

### Storage Elastic Modulus

There was used a frame having a size of 50 mm×50 mm and a thickness of 1 mm. Each resin composition was sandwiched by two pieces of a PET film that had been subjected to a mold release treatment and had a thickness of 50 μm (E7006 by TOYOBO CO., LTD.), and a vacuum press machine (by Nikko-Materials Co., Ltd.) was then used to perform molding at 160° C. for 5 min, thereby obtaining a cured product. The cured product produced was then cut into a piece(s) having dimensions of length 20 mm×width 5 mm×thickness 1 mm; a dynamic mechanical analyzer such as DMA-Q800 (by TA Instruments) was then used to measure a storage elastic modulus thereof at 25° C. at a temperature rising rate of 5° C./min and a frequency of 10 Hz, and within a temperature range of −50 to 200° C.

### Hardness

Each resin composition prepared was poured into an aluminum petri dish having a diameter of 50 mm and a thickness of 10 mm, and was molded at 160° C. for 5 min so as to obtain a cured product. The hardness of the cured product obtained was measured in accordance with the method described in JIS K 6253-3:2012, using a type D durometer where the measurement was conducted at a measurement temperature of 25° C.

### Warpage Property

Each resin composition prepared was applied to form a film having a size of 350 mm×350 mm and a thickness of 100 μm. A film laminator V-100 (by Nikko-Materials Co., Ltd.) was used to laminate the film produced by application on a silicon wafer having a diameter of 300 mm and a thickness of 750 μm, followed by heating the same at 160° C. for 5 min to produce a cured product on the silicon wafer. After cooling the cured product produced to 25° C., one end of the silicon wafer was fixed to a table, and there was measured a distance (height) from the table to the other end of the silicon wafer that was not fixed to the table, where examples exhibiting a height of not larger than 5 mm were marked “favorable,” and examples exhibiting a height of larger than 5 mm were marked “unfavorable.”

### Crack Resistance

There was prepared a sample with a silicon chip having a size of 10 mm×10 mm and a thickness of 0.75 mm being mounted on a glass epoxy printed-wiring board having a size of 32 mm×32 mm and a thickness of 1.6 mm, followed by performing transfer molding at 160° C. and 6.9 N/mm² for a curing time of 5 min to obtain a semiconductor device in which a molded size of the curable resin was 28 mm×28 mm, and a molded thickness thereof was 1.2 mm. Next, 20 of such semiconductor devices produced were each subjected to a thermal cycle test (TCT) where a cycle of −40° C./30 min, 150° C./30 min was repeated for 1,000 cycles, and the number of the semiconductor devices exhibiting cracks in the curable resin was counted.

### Dielectric Property and Heat Resistance

There was used a frame having a size of 70 mm×70 mm and a thickness of 200 μm. Each resin composition was sandwiched by two pieces of a PET film that had been subjected to a mold release treatment and had a thickness of 50 μm (E7006 by TOYOBO CO., LTD.), and a vacuum press machine (by Nikko-Materials Co., Ltd.) was then used to perform molding at 160° C. for 5 min, thereby obtaining a cured product (molded film). After obtaining a cured resin film by post-curing the molded film at 180° C. for 1 hour, a network analyzer (E5063-2D5 by Keysight Technologies) and a stripline (by KEYCOM Corporation) were connected using the cured resin film to measure a relative permittivity and dielectric tangent thereof at frequencies of 10 GHz and 28 GHz.

Further, the relative permittivity and dielectric tangent of this cured resin film were likewise measured at the frequencies of 10 GHz and 28 GHz after leaving the same at 150° C. for 48 hours.

TABLE 3

| Maleimide compound | A-1-2 | A-2-2 | A-3-2 | A-4-2 | A-5-2 | A-6-2 | A′-1-2 | A′-2-2 | A′-3-2 | A′-4-2 |
|---|---|---|---|---|---|---|---|---|---|---|
| Dimer:Trimer | 98:2 | 98:2 | 95:5 | 99.2:0.8 | 96:4 | 99.2:0.8 | 95:5 | 80:20 | 93:7 | 80:20 |
| Hydrogenation | Hydro- | Hydro- | Hydro- | Hydro- | Hydro- | Hydro- | Non-hydro- | Non-hydro- | Hydro- | Non-hydro- |
| treatment | genated | genated | genated | genated | genated | genated | genated | genated | genated | genated |

TABLE 4-1

| | | | Working example | | | | | |
|---|---|---|---|---|---|---|---|---|
| Composition table (part by mass) | | | 1-2 | 2-2 | 3-2 | 4-2 | 5-2 | 6-2 |
| (A) | A-1-2 | | 100 | | | | | |
| Component | A-2-2 | | | 100 | | | | |
| | A-3-2 | | | | 100 | | | |
| | A-4-2 | | | | | 100 | | |
| | A-5-2 | | | | | | 100 | |
| | A-6-2 | | | | | | | 100 |
| | A′-1-2 | | | | | | | |
| | A′-2-2 | | | | | | | |
| | A′-3-2 | | | | | | | |
| | A′-4-2 | | | | | | | |
| (B) | B-1-2 | | 2 | 2 | 2 | 2 | 2 | 2 |
| Component | | | | | | | | |
| Evaluation | Storage elastic | MPa | 500 | 300 | 900 | 400 | 600 | 100 |
| results | modulus | | | | | | | |
| | Hardness | Type D | 40 | 35 | 50 | 40 | 45 | 10 |
| | Warpage property | | Favorable | Favorable | Favorable | Favorable | Favorable | Favorable |
| | Crack resistance | | 0/20 | 1/20 | 2/20 | 1/20 | 0/20 | 0/20 |
| | Relative permittivity at | | 2.51 | 2.52 | 2.50 | 2.51 | 2.51 | 2.50 |
| | 10 GHz (Initial) | | | | | | | |
| | Relative permittivity at | | 2.52 | 2.54 | 2.50 | 2.53 | 2.53 | 2.50 |
| | 10 GHz(After heat | | | | | | | |
| | treatment) | | | | | | | |
| | Relative permittivity at | | 2.49 | 2.51 | 2.48 | 2.49 | 2.49 | 2.48 |
| | 28 GHz (Initial) | | | | | | | |
| | Relative permittivity at | | 2.49 | 2.53 | 2.48 | 2.50 | 2.50 | 2.48 |
| | 28 GHz(After heat | | | | | | | |
| | treatment) | | | | | | | |
| | Dielectric tangent at | | 0.0022 | 0.0022 | 0.0022 | 0.0022 | 0.0022 | 0.0022 |
| | 10 GHz (Initial) | | | | | | | |
| | Dielectric tangent at | | 0.0029 | 0.0031 | 0.0027 | 0.0030 | 0.0029 | 0.0027 |
| | 10 GHz(After heat | | | | | | | |
| | treatment) | | | | | | | |
| | Dielectric tangent at | | 0.0021 | 0.0023 | 0.0021 | 0.0022 | 0.0022 | 0.0021 |
| | 28 GHz (Initial) | | | | | | | |
| | Dielectric tangent at | | 0.0027 | 0.0030 | 0.0026 | 0.0029 | 0.0027 | 0.0026 |
| | 28 GHz(After heat | | | | | | | |
| | treatment) | | | | | | | |

TABLE 4-2

| | | | Comparative example | | | |
|---|---|---|---|---|---|---|
| Composition table (part by mass) | | | 1-2 | 2-2 | 3-2 | 4-2 |
| (A) | A-1-2 | | | | | |
| Component | A-2-2 | | | | | |
| | A-3-2 | | | | | |
| | A-4-2 | | | | | |
| | A-5-2 | | | | | |
| | A-6-2 | | | | | |
| | A′-1-2 | | 100 | | | |
| | A′-2-2 | | | 100 | | |
| | A′-3-2 | | | | 100 | |
| | A′-4-2 | | | | | 100 |
| (B) | B-1-2 | | 2 | 2 | 2 | 2 |
| Component | | | | | | |
| Evaluation | Storage elastic | MPa | 1000 | 1800 | 1400 | 1100 |
| results | modulus | | | | | |
| | Hardness | Type D | 50 | 80 | 70 | 55 |
| | Warpage property | | Favorable | Unfavorable | Unfavorable | Unfavorable |
| | Crack resistance | | 4/20 | 12/20 | 12/20 | 3/20 |
| | Relative permittivity at | | 2.52 | 2.51 | 2.52 | 2.52 |
| | 10 GHz (Initial) | | | | | |
| | Relative permittivity at | | 2.56 | 2.52 | 2.54 | 2.56 |
| | 10 GHz(After heat | | | | | |
| | treatment) | | | | | |
| | Relative permittivity at | | 2.51 | 2.49 | 2.51 | 2.50 |
| | 28 GHz (Initial) | | | | | |
| | Relative permittivity at | | 2.55 | 2.49 | 2.53 | 2.53 |
| | 28 GHz(After heat | | | | | |
| | treatment) | | | | | |
| | Dielectric tangent at | | 0.0021 | 0.0028 | 0.0023 | 0.0025 |
| | 10 GHz (Initial) | | | | | |
| | Dielectric tangent at | | 0.0035 | 0.0050 | 0.0038 | 0.0040 |
| | 10 GHz(After heat | | | | | |
| | treatment) | | | | | |
| | Dielectric tangent at | | 0.0022 | 0.0031 | 0.0023 | 0.0023 |
| | 28 GHz (Initial) | | | | | |
| | Dielectric tangent at | | 0.0034 | 0.0053 | 0.0035 | 0.0038 |
| | 28 GHz(After heat | | | | | |
| | treatment) | | | | | |

As can be seen from the above results, the cured products of the compositions of the present invention each exhibited a small warpage due to their low elasticities and low hardnesses, an excellent crack resistance, excellent dielectric properties even at high frequencies, and small changes in dielectric properties even after being left under a high temperature for a long period of time.

### Example 3. Composition Using Component (A) Represented by Formula (1-3)

### (A) Maleimide Compound

### Synthesis Example 1-3

An amic acid was synthesized by adding 205.26 g (0.50 mol) of BAPP (2,2-bis[4-(4-aminophenoxy)phenyl]propane by SEIKA CORPORATION), 130.87 g (0.60 mol) of PMDA (pyromellitic dianhydride by Lonza) and 500 g of toluene into a 2 L glass four-necked flask equipped with a stirrer, a Dean-Stark apparatus, a cooling condenser and a thermometer, and then stirring them at 80° C. for 3 hours. Next, the temperature was directly raised to 110° C., where stirring was performed for 4 hours while distilling away water produced as a by-product, thereby synthesizing a block copolymer.

Next, 267.5 g (0.50 mol) of Priamine-1075 (by Croda Japan K.K., hydrogenated, dimer diamine/trimer triamine≈98/2) were added into the flask containing the block polymer solution that had been cooled to room temperature, followed by performing stirring at 80° C. for 3 hours to synthesize an amic acid. Next, the temperature was directly raised to 110° C., where stirring was performed for 4 hours while distilling away water produced as a by-product, thereby synthesizing a dual-end diamine.

After cooling the flask containing the dual-end diamine solution obtained to room temperature, 34.32 g (0.35 mol) of maleic anhydride were added, followed by heating the solution again so as to perform stirring at 80° C. for another 3 hours, thereby synthesizing an amic acid. Next, the temperature was directly raised to 110° C., where stirring was performed for 15 hours while distilling away water produced as a by-product, followed by washing the mixture with 500 g of water 5 times, and then subjecting the washed product to stripping so as to obtain a toluene varnish containing 50% by mass of the maleimide compound (A-1-3, number average molecular weight 5,500).

As for synthesis examples other than the synthesis example 1-3 and the comparative synthesis examples, maleimide compounds were obtained in a similar manner as the synthesis example 1-3, except for the changes made to the compositions of the resin solutions as shown in Table 5.

TABLE 5

| | | Diamine other than | | |
|---|---|---|---|---|
| | | dimer diamine and | | Dimer:Trimer |
| | Acid anhydride | trimer triamine | Dimer diamine | (Mass ratio) |
| Synthesis example1-3 | PMDA | BAPP | Priamine-1075 | 98:2 |
| (A-1-3) | 130.87 g (0.60 mol) | 205.26 g (0.50 mol) | 267.25 g (0.50 mol) | |
| Synthesis example2-3 | PMDA | BAPP | Priamine-1075 | 98:2 |
| (A-2-3) | 235.57 g (1.08 mol) | 369.47 g (0.90 mol) | 267.25 g (0.10 mol) | |
| Synthesis example3-3 | PMDA | BAPP | Priamine-1075 | 98:2 |
| (A-3-3) | 209.40 g (0.96 mol) | 328.42 g (0.80 mol) | 267.25 g (0.52 mol) | |
| Synthesis example4-3 | PMDA | BAPP | Priamine-1075 | 98:2 |
| (A-4-3) | 91.61 g (0.42 mol) | 143.69 g (0.35 mol) | 267.25 g (0.53 mol) | |
| Synthesis example5-3 | PMDA | BAPP | Priamine-1075 | 98:2 |
| (A-5-3) | 78.52 g (0.36 mol) | 123.16 g (0.30 mol) | 267.25 g (0.54 mol) | |
| Synthesis example6-3 | PMDA | BAPP | Priamine-1074 | 95:5 |
| (A-6-3) | 130.87 g (0.60 mol) | 205.26 g (0.50 mol) | 267.25 g (0.50 mol) | |
| Synthesis example7-3 | PMDA | BAPP | Purified Priamine-1075 | 99.2:0.8 |
| (A-7-3) | 130.87 g (0.60 mol) | 205.26 g (0.50 mol) | 267.25 g (0.50 mol) | |
| Comparative synthesis | PMDA | BAPP | Priamine-1073 | 95:5 |
| example8-3 (A-8-3) | 130.87 g (0.60 mol) | 205.26 g (0.50 mol) | 267.25 g (0.50 mol) | |
| Comparative synthesis | PMDA | BAPP | Priamine-1071 | 80:20 |
| example9-3 (A-9-3) | 130.87 g (0.60 mol) | 205.26 g (0.50 mol) | 267.25 g (0.50 mol) | |
| Comparative synthesis | PMDA | BAPP | Priamine-1071 | 90:10 |
| example 10-3 (A-10-3) | 130.87 g (0.60 mol) | 205.26 g (0.50 mol) | 144.45 g (0.27 mol) | |
| | | | ′Priamine-1073 | |
| | | | 125.35 g (0.23 mol) | |
| Synthesis example11-3 | PMDA | 1,4-BAC | Priamine-1075 | 98:2 |
| (A-11-3) | 130.87 g (0.60 mol) | 71.12 g (0.50 mol) | 267.25 g (0.50 mol) | |
| Synthesis example 12-3 | ODPA | BAPP | Priamine-1075 | 98:2 |
| (A-12-3) | 186.13 g (0.60 mol) | 205.26 g (0.50 mol) | 267.25 g (0.50 mol) | |
| Synthesis example 13-3 | ODPA | 1,4-BAC | Priamine-1075 | 98:2 |
| (A-13-3) | 186.13 g (0.60 mol) | 71.12 g (0.50 mol) | 267.25 g (0.50 mol) | |

| | | Molar ratio | | Number | | |
|---|---|---|---|---|---|---|
| | | between group | | average | | |
| | | D and group B | | molecular | | |
| | Hydrogenation | D/B | | weight | | |
| | treatment | (molar ratio) | Maleic anhydride | (Mn) | m | n |
| Synthesis example1-3 | Hydrogenated | 50/50 | 68.62 g (0.70 mol) | 5,500 | 1 | 6 |
| (A-1-3) | | | | | | |
| Synthesis example2-3 | Hydrogenated | 10/90 | 68.62 g (0.70 mol) | 8,100 | 1 | 13 |
| (A-2-3) | | | | | | |
| Synthesis example3-3 | Hydrogenated | 20/80 | 68.62 g (0.70 mol) | 7,600 | 1 | 10 |
| (A-3-3) | | | | | | |
| Synthesis example4-3 | Hydrogenated | 65/35 | 68.62 g (0.70 mol) | 4,300 | 1 | 4 |
| (A-4-3) | | | | | | |
| Synthesis example5-3 | Hydrogenated | 70/30 | 68.62 g (0.70 mol) | 4,000 | 1 | 3 |
| (A-5-3) | | | | | | |
| Synthesis example6-3 | Hydrogenated | 50/50 | 68.62 g (0.70 mol) | 5,400 | 1 | 6 |
| (A-6-3) | | | | | | |
| Synthesis example7-3 | Hydrogenated | 50/50 | 68.62 g (0.70 mol) | 5,500 | 1 | 6 |
| (A-7-3) | | | | | | |
| Comparative synthesis | Non- | 50/50 | 68.62 g (0.70 mol) | 5,400 | 1 | 6 |
| example8-3 (A-8-3) | hydrogenated | | | | | |
| Comparative synthesis | Non- | 50/50 | 68.62 g (0.70 mol) | 5,900 | 1 | 6 |
| example9-3 (A-9-3) | hydrogenated | | | | | |
| Comparative synthesis | Non- | 50/50 | 68.62 g (0.70 mol) | 5,800 | 1 | 6 |
| example 10-3 (A-10-3) | hydrogenated | | | | | |
| Synthesis example11-3 | Hydrogenated | 50/50 | 68.62 g (0.70 mol) | 5,200 | 1 | 6 |
| (A-11-3) | | | | | | |
| Synthesis example 12-3 | Hydrogenated | 50/50 | 68.62 g (0.70 mol) | 5,500 | 1 | 6 |
| (A-12-3) | | | | | | |
| Synthesis example 13-3 | Hydrogenated | 50/50 | 68.62 g (0.70 mol) | 5,500 | 1 | 6 |
| (A-13-3) | | | | | | |

Purified Priamine-1075: Diamine obtained by subjecting 300 g of Priamine-1075 to thin film distillation at 200° C. for 60 min, and having a hydrogenated main chain, in which the dimer ratio was dimer:trimer≈99.2:0.8.
Priamine-1074 (by Croda Japan K.K., hydrogenated, dimer:trimer≈95:5)
Priamine-1073 (by Croda Japan K.K., non-hydrogenated, dimer:trimer≈95:5)
Priamine-1071 (by Croda Japan K.K., non-hydrogenated, dimer:trimer≈80:20)
1,4-BAC (1,4-bis(aminomethyl)cyclohexane by Tokyo Chemical Industry Co., Ltd.)
ODPA (oxydiphthalic anhydride by Manac Incorporated.)

### (A-14-3): Bis-(3-ethyl-5-methyl-maleimidephenyl)methane (BMI-4000 by Daiwakasei Industry Co., LTD., for Use in Comparative Example)

### (A-15-3): Bis(3-ethyl-5-methyl-4-maleimidephenyl)methane (BMI-5100 by Daiwakasei Industry Co., LTD., for Use in Comparative Example)

### (A-16-3): Maleimide Compound Represented by the Following Formula (MIR-3000 by Nippon Kayaku Co., Ltd., for Use in Comparative Example)

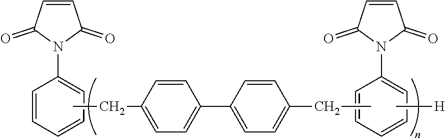

### (B) Catalyst

### (B-1-3): 2,5-dimethyl-2,5-di(t-butylperoxy)hexane (Trigonox 101 by KAYAKU NOURYON CORPORATION)

### Sample Preparation

The components were put into a plastic container at the compounding ratios shown in Tables 6 and 7, and a THINKY mixer (Awatori Rentaro ARE-310 by THINKY CORPORATION) was then used to mix them so as to obtain each resin composition in the form of a varnish (resin varnish).

### Production of Uncured Resin Film

A roller coater was used to apply the resin varnish prepared by the above procedure to a PET film that had been subjected to a mold release treatment and had a thickness of 50 μm (TN-010 by TOYOBO STC CO., LTD), followed by drying the same at 120° C. for 10 min to obtain an uncured resin film having a thickness of 50 μm.

### Dielectric Property and Heat Resistance

There was used a frame having a size of 70 mm×70 mm and a thickness of 200 μm. Each resin composition was sandwiched by two pieces of a PET film that had been subjected to a mold release treatment and had a thickness of 50 μm (E7006 by TOYOBO CO., LTD.), and a vacuum press machine (by Nikko-Materials Co., Ltd.) was then used to perform molding at 180° C. for 5 min, thereby obtaining a cured product (molded film). After obtaining a cured resin film by post-curing the molded film at 180° C. for 1 hour under a nitrogen atmosphere, a network analyzer (E5063-2D5 by Keysight Technologies) and a stripline (by KEYCOM Corporation) were connected using the cured resin film to measure a relative permittivity and dielectric tangent thereof at frequencies of 10 GHz and 28 GHz.

Further, the relative permittivity and dielectric tangent of this cured resin film were likewise measured at the frequencies of 10 GHz and 28 GHz after leaving the same at 150° C. for 48 hours.

### Glass-Transition Temperature

There was used a frame having a length of 70 mm, a width of 70 mm and a thickness of 200 μm. Each resin composition was sandwiched by two pieces of a PET film that had been subjected to a mold release treatment and had a thickness of 50 μm (E7006 by TOYOBO CO., LTD.), and a vacuum press machine (by Nikko-Materials Co., Ltd.) was then used to perform molding at 180° C. for 5 min, thereby obtaining a cured product (molded film). After obtaining a cured resin film by post-curing the molded film at 180° C. for 1 hour under a nitrogen atmosphere, the cured resin film was cut into an appropriate size, and the glass-transition temperature (Tg) thereof was then measured by DMA-800 which is manufactured by TA Instruments.

### Coefficient of Thermal Expansion

There was used a mold having a length of 15 mm, a width of 5 mm and a thickness of 5 mm. Each resin composition was sandwiched by two pieces of a PET film that had been subjected to a mold release treatment and had a thickness of 50 μm (E7006 by TOYOBO CO., LTD.), and a vacuum press machine (by Nikko-Materials Co., Ltd.) was then used to perform molding at 180° C. for 5 min, thereby obtaining a cured product. A test piece was then obtained by post-curing the cured product at 180° C. for 1 hour under a nitrogen atmosphere. A thermomechanical analyzer (TMA8310 by Rigaku Corporation) was then used to perform measurement on the test piece in a range of 0 to 40° C. so as to calculate its coefficient of thermal expansion.

### Peeling Strength (Adhesiveness to Copper Foil)

There was used a SUS 304 plate having a length of 75 mm, a width of 25 mm and a thickness of 1.0 mm. The uncured resin film with the PET film was then placed on one surface of such SUS 304 plate so that the resin composition surface of the film would come into contact with the one surface of the SUS 304 plate, followed by performing lamination at 100° C. and 0.3 MPa for 60 sec. After the lamination was over, the PET film was removed, and an 18 μm-thick copper foil (by MITSUI MINING & SMELTING CO., LTD., Rz: 0.6 μm) was then placed on and brought into contact with the resin composition surface exposed, followed by performing lamination at 100° C. and 0.3 MPa for 60 sec. After the lamination was over, an adhesion test piece was produced by curing the laminated product at 180° C. for 1 hour under a nitrogen atmosphere.

In order to evaluate adhesiveness, there was measured a 90° peeling adhesion strength (kN/m) when peeling the copper foil of each adhesion test piece from SUS 304 at a temperature of 23° C. and a tension rate of 50 mm/min, in accordance with JIS-C-6481 “Test methods of copper-clad laminates for printed wiring boards.”

TABLE 6

| Composition table | | Working example | | | | | | | | | |
|---|---|---|---|---|---|---|---|---|---|---|---|
| (part by mass) | | 1-3 | 2-3 | 3-3 | 4-3 | 5-3 | 6-3 | 7-3 | 8-3 | 9-3 | 10-3 |
| (A)Component | A-1-3 | 100.0 | | | | | | | | | |
| | A-2-3 | | 100.0 | | | | | | | | |
| | A-3-3 | | | 100.0 | | | | | | | |
| | A-4-3 | | | | 100.0 | | | | | | |
| | A-5-3 | | | | | 100.0 | | | | | |
| | A-6-3 | | | | | | 100.0 | | | | |
| | A-7-3 | | | | | | | 100.0 | | | |
| | A-11-3 | | | | | | | | 100.0 | | |
| | A-12-3 | | | | | | | | | 100.0 | |
| | A-13-3 | | | | | | | | | | 100.0 |
| (B)Component | B-1-3 | 2.0 | 2.0 | 2.0 | 2.0 | 2.0 | 2.0 | 2.0 | 2.0 | 2.0 | 2.0 |
| Toluene | | 100.0 | 100.0 | 100.0 | 100.0 | 100.0 | 100.0 | 100.0 | 100.0 | 100.0 | 100.0 |
| Relative permit- | (Initial) | 2.60 | 2.89 | 2.62 | 2.54 | 2.49 | 2.68 | 2.60 | 2.65 | 2.56 | 2.61 |
| tivity at 10 GHz | | | | | | | | | | | |
| Relative permit- | (After heat | 2.60 | 2.89 | 2.62 | 2.54 | 2.49 | 2.68 | 2.60 | 2.69 | 2.56 | 2.62 |
| tivity at 10 GHz | treatment) | | | | | | | | | | |
| Relative permit- | (Initial) | 2.65 | 2.91 | 2.60 | 2.55 | 2.48 | 2.70 | 2.65 | 2.69 | 2.56 | 2.63 |
| tivity at 28 GHz | | | | | | | | | | | |
| Relative permit- | (After heat | 2.65 | 2.92 | 2.60 | 2.57 | 2.50 | 2.71 | 2.65 | 2.71 | 2.56 | 2.63 |
| tivity at 28 GHz | treatment) | | | | | | | | | | |
| Dielectric tangent | (Initial) | 0.0013 | 0.0032 | 0.0019 | 0.0015 | 0.0013 | 0.0017 | 0.0013 | 0.0015 | 0.0015 | 0.0015 |
| at 10 GHz | | | | | | | | | | | |
| Dielectric tangent | (After heat | 0.0014 | 0.0033 | 0.0019 | 0.0016 | 0.0015 | 0.0018 | 0.0013 | 0.0017 | 0.0015 | 0.0016 |
| at1 0 GHz | treatment) | | | | | | | | | | |
| Dielectric tangent | (Initial) | 0.0018 | 0.0034 | 0.0024 | 0.0014 | 0.0013 | 0.0021 | 0.0018 | 0.0019 | 0.0015 | 0.0017 |
| at 28 GHz | | | | | | | | | | | |
| Dielectric tangent | (After heat | 0.0018 | 0.0034 | 0.0024 | 0.0015 | 0.0015 | 0.0022 | 0.0018 | 0.0021 | 0.0015 | 0.0019 |
| at 28 GHz | treatment) | | | | | | | | | | |
| Glass-transition | ° C. | 172 | 200 | 182 | 139 | 118 | 175 | 169 | 178 | 156 | 161 |
| temperature | | | | | | | | | | | |
| Coefficient of | ppm/K | 85 | 71 | 76 | 92 | 99 | 85 | 87 | 82 | 91 | 89 |
| thermal expansion | | | | | | | | | | | |
| Peeling strength | kN/m | 1.0 | 0.6 | 0.8 | 1.1 | 1.2 | 1.0 | 1.1 | 0.8 | 1.4 | 1.1 |

TABLE 7

| | | Comparative example | | | | | |
|---|---|---|---|---|---|---|---|
| Composition table (part by mass) | | 1-3 | 2-3 | 3-3 | 4-3 | 5-3 | 6-3 |
| (A)Component | A-8-3 | 100.0 | | | | | |
| | A-9-3 | | 100.0 | | | | |
| | A-10-3 | | | 100.0 | | | |
| | A-14-3 | | | | 100.0 | | |
| | A-15-3 | | | | | 100.0 | |
| | A-16-3 | | | | | | 100.0 |
| (B)Component | B-1-3 | 2.0 | 2.0 | 2.0 | 2.0 | 2.0 | 2.0 |
| Toluene | | 100.0 | 100.0 | 100.0 | | | 100.0 |
| THF | | | | | 50.0 | 50.0 | |
| Acetonitrile | | | | | 50.0 | 50.0 | |
| Relative permittivity at | (Initial) | 2.60 | 2.82 | 2.70 | 3.12 | 2.92 | 2.83 |
| 10 GHZ | | | | | | | |
| Relative permittivity at | (After heat | 0.0013 | 0.0021 | 0.0015 | | | 2.80 |
| 10 GHz | treatment) | | | | | | |
| Relative permittivity at | (Initial) | 2.65 | 2.82 | 2.72 | 3.29 | 3.05 | 2.79 |
| 28 GHz | | | | | | | |
| Relative permittivity at | (After heat | 0.0014 | 0.0025 | 0.0016 | 3.29 | 3.05 | 2.79 |
| 28 GHZ | treatment) | | | | | | |
| Dielectric tangent at | (Initial) | 2.71 | 2.85 | 2.76 | 0.017 | 0.020 | 0.0054 |
| 10 GHz | | | | | | | |
| Dielectric tangent at | (After heat | 0.0021 | 0.0029 | 0.0023 | 0.017 | 0.020 | 0.0054 |
| 10 GHz | treatment) | | | | | | |
| Dielectric tangent at | (Initial) | 2.72 | 2.86 | 2.79 | 0.020 | 0.022 | 0.0068 |
| 28 GHz | | | | | | | |
| Dielectric tangent at | (After heat | 0.0025 | 0.0032 | 0.0028 | 0.021 | 0.022 | 0.0068 |
| 28 GHZ | treatment) | | | | | | |
| Glass-transition | ° C. | 170 | 179 | 171 | 270 | 264 | 221 |
| temperature | | | | | | | |
| Coefficient of thermal | ppm/K | 89 | 79 | 83 | 74 | 63 | 58 |
| expansion | | | | | | | |
| Peeling strength | kN/m | 1.0 | 0.8 | 0.9 | <0.1 | <0.1 | 0.2 |

### DESCRIPTION OF THE SYMBOLS

1 Prepreg
2 Curable resin composition
3 Fiber base material
11 Metal-clad laminate
12 Insulating layer
13 Metal foil
21 Printed-wiring board
22 Wiring layer

What is claimed is:

1. A curable resin composition comprising:
(A) a maleimide compound represented by the following general formula (1) 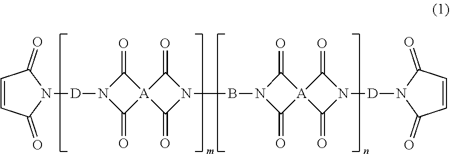
wherein D independently represents a dimer acid- and trimer acid-derived hydrocarbon group; B independently represents a cyclic structure-containing divalent hydrocarbon group other than a dimer acid- and trimer acid-derived hydrocarbon group; A independently represents a tetravalent organic group having a cyclic structure; m is 0 to 100, n is 0 to 100, where no restrictions are imposed on an order of each repeating unit identified by m and n, and a bonding pattern may be alternate, block or random; and
(B) a catalyst,
wherein D in the formula (1) is a group in which dimer acid-derived hydrocarbon group occupies 95% by mass or more of the dimer acid- and trimer acid-derived hydrocarbon group, and is a hydrogenated group.

2. The curable resin composition according to claim 1, wherein the maleimide compound as the component (A) is a compound represented by the following formula (1-1) when m=n=0 in the formula (1) 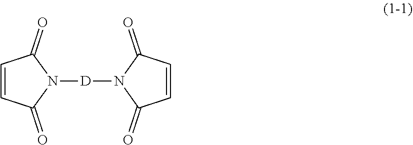
wherein D represents a dimer acid- and trimer acid-derived hydrocarbon group.

3. The curable resin composition according to claim 2, wherein the maleimide compound as the component (A) has a viscosity of not higher than 7.0 Pa s when measured by a method described in JIS Z8803:2011 and by a Brookfield-type rotary viscometer at a measurement temperature of 25° C. and a spindle rotation speed of 5 rpm.

4. The curable resin composition according to claim 2, wherein the maleimide compound as the component (A) has a number average molecular weight of not larger than 1,150.

5. The curable resin composition according to claim 1, wherein the maleimide compound as the component (A) is a compound represented by the following formula (1-2) when m is not 0, but n=0 in the formula (1) 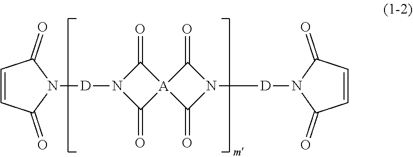
wherein D independently represents a dimer acid- and trimer acid-derived hydrocarbon group, A independently represents a tetravalent organic group having a cyclic structure, m′ is 1 to 100.

6. The curable resin composition according to claim 5, wherein a cured product of the curable resin composition has a storage elastic modulus of smaller than 1,000 MPa when measured by a method described in JIS K7244-4:1999 and by a dynamic mechanical analyzer at a frequency of 10 Hz and a temperature rising rate of 5° C./min in a temperature range of −50 to 200° C.

7. The curable resin composition according to claim 5, wherein a cured product of the curable resin composition has a hardness of not higher than D50 when measured by a method described in JIS K 6253-3:2012 and by a type D durometer at a measurement temperature of 25° C.

8. The curable resin composition according to claim 1, wherein the maleimide compound as the component (A) is a compound represented by the following formula (1-3) when neither m nor n is 0 in the formula (1) 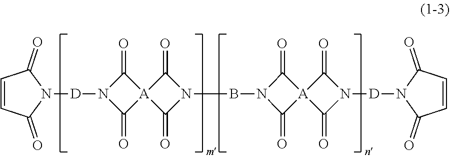
wherein D independently represents a dimer acid- and trimer acid-derived hydrocarbon group; B independently represents a cyclic structure-containing divalent hydrocarbon group other than a dimer acid- and trimer acid-derived hydrocarbon group; A independently represents a tetravalent organic group having a cyclic structure; m′ is 1 to 100, n′ is 1 to 100, where no restrictions are imposed on an order of each repeating unit identified by m′ and n′, and a bonding pattern may be alternate, block or random.

9. The curable resin composition according to claim 8, wherein a molar ratio between the group D and the group B in the maleimide compound as the component (A) is D/B=20/80 to 65/35.

10. The curable resin composition according to claim 9, wherein B in the formula (1) is a group having an aliphatic ring and/or an aromatic ring.

11. The curable resin composition according to claim 8, wherein A in the formula (1) is any one of the tetravalent organic groups represented by the following structural formulae 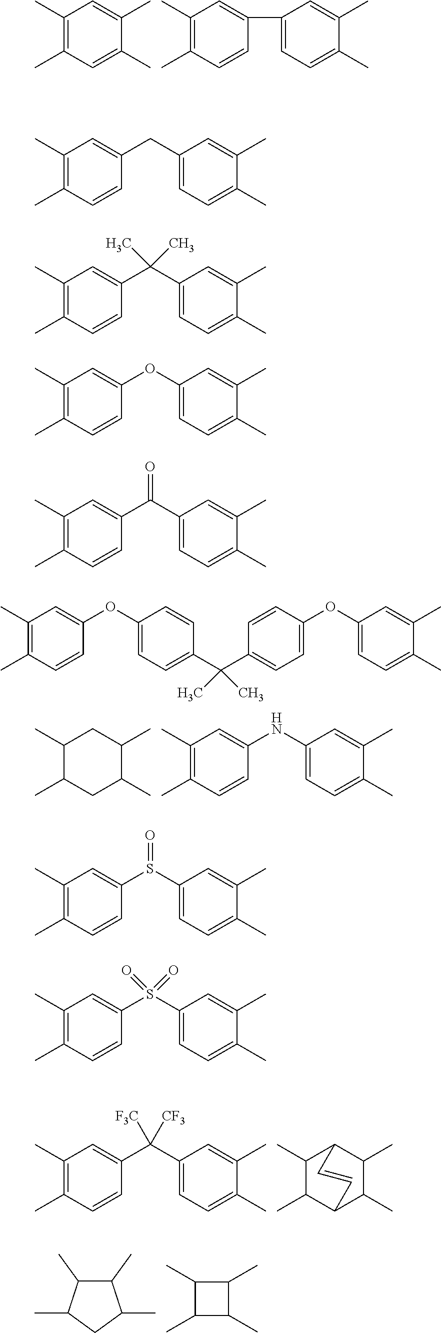 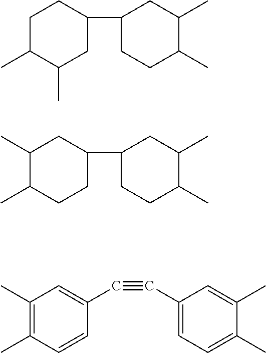
wherein bonds that are yet unbonded to substituent groups are to be bonded to carbonyl carbons forming cyclic imide structures in the formula (1-3).

12. The curable resin composition according to claim 8, wherein the curable resin composition has a glass-transition temperature of higher than 120° C. when measured by dynamic mechanical analysis (DMA) after curing.

13. The curable resin composition according to claim 1, wherein the catalyst as the component (B) is at least one selected from an organic peroxide, an anionic polymerization initiator and a photocuring initiator.

14. A semiconductor encapsulation material comprising the curable resin composition according to claim 1.

15. An adhesive comprising the curable resin composition according to claim 1.

16. An adhesive film comprising the curable resin composition according to claim 1.

17. A prepreg comprising the curable resin composition according to claim 1 and a fiber base material.

18. An interlayer insulating material comprising the curable resin composition according to claim 1.

19. A printed-wiring board comprising a cured product of the curable resin composition according to claim 1.
